(19) United States
(12) Patent Application Publication
(10) Pub. No.: US 2020/0303799 A1
(43) Pub. Date: Sep. 24, 2020

(54) VERTICAL TRANSITIONS FOR MICROWAVE AND MILLIMETER WAVE COMMUNICATIONS SYSTEMS HAVING MULTI-LAYER SUBSTRATES

(71) Applicant: CommScope Technologies LLC, Hickory, NC (US)

(72) Inventors: Huan WANG, Richardson, TX (US); Michael BROBSTON, Allen, TX (US)

(21) Appl. No.: 16/755,921

(22) PCT Filed: Oct. 12, 2018
(86) PCT No.: PCT/US2018/055630

§ 371 Date: Apr. 14, 2020

Related U.S. Application Data
(60) Provisional application No. 62/573,244, filed on Oct. 17, 2017.

(51) Int. Cl. H01P 3/08; H05K 1/02; H05K 1/11

(52) U.S. Cl. CPC H01P 3/08; H05K 1/0237; H05K 2201/09618; H05K 2201/09509; H05K 1/115

(57) ABSTRACT

Radio frequency transmission lines in a multi-layer printed circuit board structure include first and second rows of ground vias that extend vertically through the printed circuit board structure. A first transmission line segment extends horizontally along a first portion of the multi-layer printed circuit board structure and a second transmission line segment extends horizontally along a second portion of the multi-layer printed circuit board structure, the second transmission line segment vertically spaced apart from the first transmission line segment. A vertical dielectric structure extends between the first and second transmission line segments and a blind ground via extends vertically through the printed circuit board structure adjacent the vertical dielectric structure.

### CROSS REFERENCE TO RELATED APPLICATION

The present application claims priority under 35 U.S.C. § 119 to U.S. Provisional Patent Application Ser. No. 62/573,244, filed Oct. 17, 2017, the entire content of which is incorporated herein by reference as if set forth in its entirety.

### FIELD

The inventive concepts described herein relate to communications systems and, more particularly, to microwave and millimeter wave communications systems.

### BACKGROUND

As wireless radio frequency (“RF”) communications systems move to higher frequencies, such as millimeter wave frequencies, the wavelength of the RF signals becomes increasingly smaller. As the wavelength decreases, the size of many of the components in an RF communications system (e.g., antenna elements, power couplers, etc.) likewise decreases. By way of example, at frequencies in the 500 to 1 GHz frequency range typical antenna radiating elements may be 4-8 inches long. At 60 GHz, the radiating elements may be sixty times smaller.

As the size of the components in a wireless RF communications system decreases, the use of system-in-package technology to implement such systems becomes more attractive. System-in-package technology refers to systems in which many or all of the components of the system are integrated into a single package. System-in-package technology may be used to reduce the cost and/or size of a system, and in some instances may improve system reliability and/or performance by reducing or eliminating external connections.

System-in-package technology has been used to implement high frequency wireless RF communications systems. For example, FIG. 1 is a schematic cross-sectional view of a conventional system-in-package transmit/receive module 10 for an X-band phased array radar application as described in M. X. Yu, A novel microstrip-to-microstrip vertical via transition in X-band multilayer packages, Hindawei, International Journal of Antennas and Propagation, Vol. 2016, Article ID 9562854, pp. 1-8. As shown in FIG. 1, the system-in-package transmit/receive module 10 includes a pair of monolithic microwave integrated circuit chips 20-1, 20-2 (one for transmit and one for receive) that are mounted on opposite sides of a multi-layer laminated structure 30 that is mounted in a metal cavity 40. The multi-layer laminated structure 30 includes a plurality of stacked dielectric layers 32 and patterned metal layers 34. Conductive vias 36 penetrate the multi-layer laminated structure 30 to provide interconnections between different layers. The use of system-in-package technology to implement the transmit/receive module 10 may reduce the size of the module 10, decrease manufacturing costs, simplify fabrication, and may also reduce losses and the noise figure of the system by shortening transmission line paths and/or by providing lower loss connections between elements of the system.

In high frequency communications systems, the electrical length of the conductive signal vias that are used to form vertical transitions through a multi-layer substrate of a system-in-package substrate may be similar to the wavelengths of the signals transmitted therethrough. Consequently, electrical discontinuities may arise that can excite unwanted transmission modes that may cause strong coupling between the vertical conductive signal via and ground planes that are included on inner layers of the multi-layer substrate.

In order to reduce the above-described effects, ground vias may be provided adjacent the conductive signal via that serve as return current paths between the opposed ground planes. The ground vias may reduce or eliminate the coupling between the conductive signal via and the ground planes. FIGS. 2 and 3 illustrate a conventional technique for implementing a vertical transition through a multi-layer substrate of a system-in-package RF communications system that connects a first transmission line on one side of the multi-layer substrate to a second transmission line on a second side of the multi-layer substrate that uses such ground vias. In particular, FIG. 2 is a schematic perspective view of a portion of the multi-layer substrate 50 that includes the conventional vertical transition, and FIG. 3 is a cross-sectional view taken along line 3-3 of FIG. 2. The conventional vertical transition illustrated in FIGS. 2-3 uses ground vias to reduce coupling between the conductive signal via and the ground planes.

The conventional vertical transition illustrated in FIGS. 2-3 interconnects first and second co-planar waveguide transmission lines. As known in the art, a co-planar waveguide is a transmission line structure that can be implemented in a printed circuit board. A co-planar waveguide transmission line includes a conductive track that is formed on a first side of a dielectric substrate of the microstrip printed circuit board, and a ground plane that is formed on a second opposed side of the dielectric substrate. A pair of ground (return) conductors are formed on either side of the conductive track on the first side of the dielectric substrate, and hence are co-planar with the conductive track. The return conductors are separated from the conductive track by respective small gaps and typically have unvarying widths along the length of the co-planar waveguide transmission line. Metal-filled ground vias are provided that connect the return conductors to the ground plane on the second side of the dielectric substrate.

As shown in FIGS. 2-3, the multi-layer substrate 50 includes a plurality of patterned metal layers 52 that are separated by a plurality of dielectric layers 54. The first co-planar transmission line 60 is implemented in the uppermost layers of the multi-layer substrate 50, and the second co-planar transmission line 70 is implemented in the lowermost layers of the multi-layer substrate 50. The first co-planar transmission line 60 includes a conductive track 62 and first and second return conductors 66-1, 66-2 that are implemented in the uppermost patterned metal layer 52. The first and second return conductors 66-1, 66-2 are separated from the conductive track 62 by respective gaps 68-1, 68-2. The gaps 68-1, 68-2 may be filled in with a dielectric material and may comprise a single continuous gap in some cases. A ground plane 64 may be formed on the uppermost internal patterned metal layer 52 underneath the conductive track 62. Note that the gaps 68-1, 68-2 between the conductive track 62 and the return conductors 66-1, 66-2 are not shown in FIG. 2 to simplify the drawing.

The second co-planar transmission line 70 includes a conductive track 72 and first and second return conductors 76-1, 76-2 that are implemented in the lowermost patterned metal layer 52. The first and second return conductors 76-1, 76-2 are separated from the conductive track 72 by respective gaps 78-1, 78-2. The gaps 78-1, 78-2 may be filled in with a dielectric material and may comprise a single continuous gap in some cases. A ground plane 74 may be formed on the lowermost internal patterned metal layer 52 above the conductive track 72.

First and second rows of ground vias 80, 82 are provided on respective sides of the first and second return conductors 66-1, 66-2, 76-1, 76-2. Each ground via 80, 82 may comprise a metal plated via (that may be metal-filled) that extends all the way through the multi-layer substrate 50. As noted above, ground planes 64, 74 may be formed on the uppermost and lowermost internal patterned metal layers 52 that are part of the first and second transmission lines 60, 70, and additional ground planes may be provided on other of the internal patterned metal layers 52. Each ground via 80, 82 may electrically connect the ground planes 64, 74 to the first or second return conductors 66-1, 66-2, 76-1, 76-2.

A conductive metal-plated signal via 90 (which may or may not be metal-filled) extends between and electrically connects the conductive tracks 62, 72 of the respective first and second transmission lines 60, 70. Vertically stacked annular metal pads 92 may be included in each patterned metal layer 52 that improve the impedance match between the conductive signal via 90 and the first and second transmission lines 60, 70. An RF signal input to the first transmission line 60 flows to the conductive signal via 90 where it takes a 90 degree turn and flow vertically through the multi-layer substrate 50 to the second transmission line 70.

Various other vertical transitions are known in the art. For example, U.S. Pat. No. 8,035,992 to Kushta illustrates another vertical transition for a multi-layer printed circuit board that is similar to the vertical transition illustrated above with reference to FIGS. 1-3. The publication entitled A Novel Through Via for Printed Circuit Board at Millimeter-Wave Frequencies by Hongyu Zhou and Farshid Aryanfar, IEEE APS (2014) pp, 1698-1699 discloses another vertical transition that uses back drilled holes to form the vertical transitions. This design may be difficult to manufacture and may exhibit unacceptably high levels of insertion loss at frequencies greater than about 10 GHz. U.S. Pat. No. 7,808,439 to Yang et al. discloses a vertical transition for a multi-layer printed circuit board that has substrate integrated waveguide transmission lines. This patent proposes using slots to couple RF signals between back-to-back substrate integrated waveguides.

While the above-described vertical transitions may provide satisfactory performance for certain frequency ranges, the performance of these structures may significantly degrade at higher frequencies.

### SUMMARY

Pursuant to embodiments of the present invention, RF transmission lines are provided that are implemented in a multi-layer printed circuit board structure. These RF transmission lines include first and second rows of ground vias that extend vertically through the multi-layer printed circuit board structure, first and second transmission line segments that extend horizontally along respective first and second portions of the multi-layer printed circuit board structure, the second transmission line segment vertically spaced apart from the first transmission line segment, a vertical dielectric structure that extends between the first and second transmission line segments, and a blind ground via that extends vertically through the printed circuit board structure positioned adjacent the vertical dielectric structure.

In some embodiments, at least one of the first and second transmission line segments extends between the first and second rows of ground vias.

In some embodiments, the blind ground via extends to one of a top surface or a bottom surface of the printed circuit board structure. In other embodiments, the blind ground via is a buried blind ground via having a top end and a bottom end that are both within an interior of the printed circuit board structure. In either case, the blind ground via may extend between the first and second rows of ground vias, and a plurality of blind ground vias may be provided between the first and second rows of ground vias.

In some embodiments, the blind ground via is configured to block one or more leakage paths for RF energy of an RF signal travelling between the first and second transmission line segments. These leakage paths may include a first leakage path through a core dielectric layer of a first printed circuit board of the multi-layer printed circuit board structure and a second leakage path through a dielectric layer that is between the first printed circuit board and a second printed circuit board of the multi-layer printed circuit board structure.

In some embodiments, the at least one blind ground via comprises a first blind ground via that vertically overlaps and is isolated from the first transmission line segment and a second blind ground via that vertically overlaps and is isolated from the second transmission line segment.

In some embodiments, the first transmission line segment may be implemented in an uppermost printed circuit board of the printed circuit board structure, and the second transmission line segment may be implemented in a lowermost printed circuit board of the printed circuit board structure. The blind ground via may comprise a first set of blind ground vias that extend completely through the uppermost printed circuit board on a first side of the vertical dielectric structure and a second set of blind ground vias that extend completely through the lowermost printed circuit board on a second side of the vertical dielectric structure that is opposite the first side.

In some embodiments, the blind ground via is between the first row of ground vias and the second row of ground vias adjacent a distal end of the first transmission line segment.

In some embodiments, the multi-layer printed circuit board structure may comprise a plurality of printed circuit boards, each printed circuit board including a core dielectric layer and at least one patterned metal layer, and a plurality of additional dielectric layers that bind the printed circuit boards together. In such embodiments, the blind ground via may extend through the core dielectric layer of at least one of the printed circuit boards. In some embodiments, the blind ground via may not extend through any of the additional dielectric layers, while in other embodiments the blind ground via may extend through at least one of the additional dielectric layers.

In some embodiments, the RF transmission line may further include a conductive signal via that extends between the first and second transmission line segments. In such embodiments, the RF transmission line may also further include a plurality of vertically spaced-apart annular metal pads that surround the conductive signal via. The RF transmission line may also include a plurality of annular void rings that define an annular dielectric column that surround the plurality of vertically spaced-apart annular metal pads, the annular dielectric column comprising the vertical dielectric structure.

In some embodiments, at least one of the first and second transmission line segments may comprise a substrate integrated waveguide structure, and the vertical dielectric structure may comprise a vertically extending dielectric slot through the multi-layer printed circuit board structure.

In some embodiments, at least one of the first and second transmission line segments may comprise a co-planar waveguide structure.

Pursuant to further embodiments of the present invention, RF transmission lines in multi-layer printed circuit board structures are provided that include first and second vertically spaced apart transmission line segments that extend horizontally along respective first and second portions of the multi-layer printed circuit board structure, a vertical dielectric structure that extends between the first and second transmission line segments, and first and second ground vias that vertically overlap the respective first and second transmission line segments.

In some embodiments, the first and second ground vias may each comprise blind ground vias that that extend vertically through the printed circuit board structure and that each have an end that terminates within an interior of the printed circuit board structure.

In some embodiments, the RF transmission line may further include first and second rows of ground vias that extend vertically through the printed circuit board structure, and at least one of the first and second transmission line segments extends between the first and second rows of ground vias.

In some embodiments, the first and second blind ground vias are each a buried blind ground via having a top end and a bottom end that are both within an interior of the printed circuit board structure.

In some embodiments, the first and second blind ground vias are each between the first and second rows of ground vias.

In some embodiments, the first and second blind ground vias are configured to block respective leakage paths for RF energy of an RF signal travelling between the first and second transmission line segments. The leakage paths may include at least a first leakage path through a core dielectric layer of a first printed circuit board of the multi-layer printed circuit board structure and a second leakage path through an adhesive dielectric layer that is between the first printed circuit board and a second printed circuit board of the multi-layer printed circuit board structure.

In some embodiments, the first and second blind ground vias are on opposed sides of the vertical dielectric path.

In some embodiments, the multi-layer printed circuit board structure may comprise a plurality of printed circuit boards, each printed circuit board including a core dielectric layer and at least one patterned metal layer, and a plurality of additional dielectric layers that bind the printed circuit boards together, and the first and second blind ground vias may each extend through the core dielectric layer of at least one of the printed circuit boards but do not extend through any of the additional dielectric layers.

In some embodiments, the multi-layer printed circuit board structure may comprise a plurality of printed circuit boards, each printed circuit board including a core dielectric layer and at least one patterned metal layer, and a plurality of additional dielectric layers that bind the printed circuit boards together, and wherein the first and second blind ground vias each extend through the core dielectric layer of at least one of the printed circuit boards and at least one of the additional dielectric layers.

In some embodiments, the RF transmission line may further include a conductive signal via that extends between the first and second transmission line segments. A plurality of vertically spaced-apart annular metal pads may surround the conductive signal via, and a plurality of annular void rings that define an annular dielectric column may surround the plurality of vertically spaced-apart annular metal pads. In some embodiments, a plurality of annular void rings that define an annular dielectric column may surround the plurality of vertically spaced-apart annular metal pads, the annular dielectric column comprising the vertical dielectric structure.

In some embodiments, at least one of the first and second transmission line segments may comprise a substrate integrated waveguide structure, and the vertical dielectric structure may comprise a vertically extending dielectric slot through the multi-layer printed circuit board structure.

In some embodiments, at least one of the first and second transmission line segments may comprise a co-planar waveguide structure.

Pursuant to still further embodiments of the present invention, RF transmission lines in multi-layer printed circuit board structures are provided that include first and second rows of ground vias that extend vertically through the multi-layer printed circuit board structure, first and second vertically spaced apart transmission line segments that extend'horizontally along a first portion of the multi-layer printed circuit board structure, and a first blind ground via that is adjacent the distal end of the first transmission line segment between the first and second rows of ground vias.

In some embodiments, the RF transmission line may further include a conductive signal via that is electrically connected to and extends between distal ends of the first and second transmission line segments.

In some embodiments, at least one of the first and second transmission line segments may extend between the first and second rows of ground vias.

In some embodiments, a top end and a bottom end of the first blind ground via may both be within an interior of the printed circuit board structure.

In some embodiments, the first blind ground via may be configured to block one or more leakage paths for RF energy of an RF signal travelling between the first and second transmission line segments

In some embodiments, the leakage paths may include at least a first leakage path through a core dielectric layer of a first printed circuit board of the multi-layer printed circuit board structure and a second leakage path through an adhesive dielectric layer that is between the first printed circuit board and a second printed circuit board of the multi-layer printed circuit board structure.

In some embodiments, the first blind ground via may vertically overlap and be isolated from the first transmission line segment, and the RF transmission line may further include a second blind ground via that vertically overlaps and is isolated from the second transmission line segment.

In some embodiments, the first transmission line segment may be implemented in an uppermost printed circuit board of the printed circuit board structure, and the second transmission line segment may be implemented in a lowermost printed circuit board of the printed circuit board structure, and the first blind ground via may extend completely through the uppermost printed circuit board on a first side of the conductive signal via and vertically overlap the second transmission line segment.

In some embodiments, a plurality of vertically spaced-apart annular metal pads may surround the conductive signal via, and a plurality of annular void rings that define an annular dielectric column may surround the plurality of vertically spaced-apart annular metal pads.

In some embodiments, the first blind ground via may be an offset blind ground via that includes first and second segments that do not vertically overlap.

Pursuant to yet additional embodiments of the present invention, methods of manufacturing an RF transmission line are provided. Pursuant to these methods, a first printed circuit board having a first transmission line segment and a first conductive ground via is formed. A second printed circuit board having a second transmission line segment and a second conductive ground via is formed. At least one additional printed circuit board having a third conductive ground via and a fourth conductive via is formed. A first additional dielectric layer is used to adhere the first printed circuit board to the at least one additional printed circuit board. A second additional dielectric layer is used to adhere the second printed circuit board to the at least one additional printed circuit board. The first conductive ground via is vertically aligned with the third conductive ground via to form a first blind ground via and the second conductive ground via is vertically aligned with the fourth conductive ground via to form a second blind ground via.

In some embodiments, the second blind ground via may vertically overlap the first transmission line segment and the first blind ground via may vertically overlap the second transmission line segment.

Pursuant to yet additional embodiments of the present invention, methods of tuning an RF transmission line having a vertical transition are provided. Pursuant to these methods, a size of a vertical cavity resonator formed in the vertical transition is changed in order to adjust a passband of the RF transmission line.

### BRIEF DESCRIPTION OF THE DRAWINGS

FIG. 1 is a schematic cross-sectional view of a conventional system-in-package transmit/receive module.

FIG. 2 is a schematic perspective view of a multi-layer substrate for a system-in-package RF communications system that includes a vertical transition.

FIG. 3 is a cross-sectional view taken along line 3-3 of FIG. 2.

FIG. 4 is a perspective view of a portion of a printed circuit board structure for a system-in-package RF communications system that includes an RF transmission line having a vertical transition.

FIG. 5 is a top plan view of the printed circuit board structure of FIG. 4.

FIG. 6 is a bottom plan view of the printed circuit board structure of FIG. 4.

FIG. 7 is a vertical cross-sectional view taken along line 7-7 of FIG. 5

FIG. 8 is a horizontal cross-sectional view taken along line 8-8 of FIG. 7.

FIG. 9 is a vertical cross-sectional view similar to the view of FIG. 7 that illustrates RF leakage paths through the printed circuit board structure.

FIG. 10 is a vertical cross-sectional view taken along line 10-10 of FIG. 5.

FIG. 11 is a graph illustrating the return loss and insertion loss performance of the RF transmission line included in the printed circuit board structure of FIGS. 4-10.

FIG. 12 is a graph of the radiation loss and dissipation loss performance of the RF transmission line included in the printed circuit board structure of FIGS. 4-10.

FIG. 13 is a top plan view of a printed circuit board structure for a system-in-package RF communications system that includes an RF transmission line having a vertical transition according to embodiments of the present invention.

FIG. 14 is a bottom plan view of the printed circuit board structure of FIG. 13.

FIG. 15 is a vertical cross-sectional view taken along line 15-15 of FIG. 13.

FIGS. 16 and 17 are horizontal cross-sectional views taken along lines 16-16 and 17-17, respectively, of FIG. 15.

FIG. 18 is a graph illustrating the return loss and insertion loss performance of the RF transmission line included in the printed circuit board structure of FIGS. 13-17.

FIG. 19 is a graph illustrating the radiation loss and the dissipation loss of the RF transmission line included in the printed circuit board structure of FIGS. 13-17.

FIG. 20 is a vertical cross-sectional view of a modified version of the printed circuit board structure of FIGS. 13-17.

FIG. 21 is a graph illustrating the return loss and insertion loss performance of the RF transmission line included in the printed circuit board structure of FIG. 20.

FIG. 22 is a graph illustrating the radiation loss and the dissipation loss for the RF transmission line included in the printed circuit board structure of FIG. 20.

FIG. 23 is a plan top view of a printed circuit board structure for a system-in-package RF communications system that includes an RF transmission line having a vertical transition according to further embodiments of the present invention.

FIG. 24 is a vertical cross-sectional view taken along line 24-24 of FIG. 23.

FIGS. 25 and 26 are horizontal cross-sections taken along lines 25-25 and 26-26, respectively, of FIG. 24.

FIG. 27 is a perspective view of a printed circuit board structure for a system-in-package RF communications system that includes an RF transmission line having a vertical transition according to still further embodiments of the present invention.

FIG. 28 is a vertical cross-sectional view taken along line 28-28 of FIG. 27.

FIGS. 29 and 30 are horizontal cross-sections taken along line 29-29 and 30-30, respectively, of FIG. 28.

FIG. 31 is a graph illustrating the return loss and insertion loss performance for the RF transmission line included in the printed circuit board structure of FIGS. 27-30.

FIG. 32 is a graph illustrating the radiation loss and the dissipation loss for the RF transmission line included in the printed circuit board structure of FIGS. 27-30.

FIG. 33 is a vertical cross-sectional view of a modified version of the printed circuit board structure of FIGS. 27-30.

FIG. 34 is a graph illustrating the return loss and insertion loss performance for the RF transmission line included in the printed circuit board structure of FIG. 33.

FIG. 35 is a graph illustrating the radiation loss and the dissipation loss for the RF transmission line included in the printed circuit board structure of FIG. 33.

FIG. 36 is a perspective view of a printed circuit board structure for a system-in-package RF communications system that includes an RF transmission line having a vertical transition according to yet further embodiments of the present invention.

FIG. 37 is a top plan view of the printed circuit board structure of FIG. 36.

FIGS. 38 and 39 are horizontal cross-sections taken along two of the internal patterned metal layers of the printed circuit board structure of FIG. 36.

FIG. 40 is a vertical cross-sectional view of a modified version of the printed circuit board structure of FIGS. 36-39.

FIG. 41 is a top plan view of a printed circuit board structure for a system-in-package RF communications system that includes an RF transmission line having a vertical transition that has filtering capabilities according to further embodiments of the present invention.

FIG. 42 is a vertical cross-sectional view taken along line 41-41 of FIG. 41.

FIG. 43 is a graph illustrating the return loss and insertion loss performance of the RF transmission line included in the printed circuit board structure of FIGS. 41-42.

FIG. 44 is a top plan view of a printed circuit board structure for a system-in-package RF communications system that includes an RF transmission line having a vertical transition that has filtering capabilities according to further embodiments of the present invention.

FIGS. 45 and 46 are vertical cross-sections taken along lines 45-45 and 46-46, respectively, of FIG. 44.

FIGS. 47-49 are horizontal cross-sections taken along lines 47-47, 48-48 and 49-49, respectively, of FIG. 46.

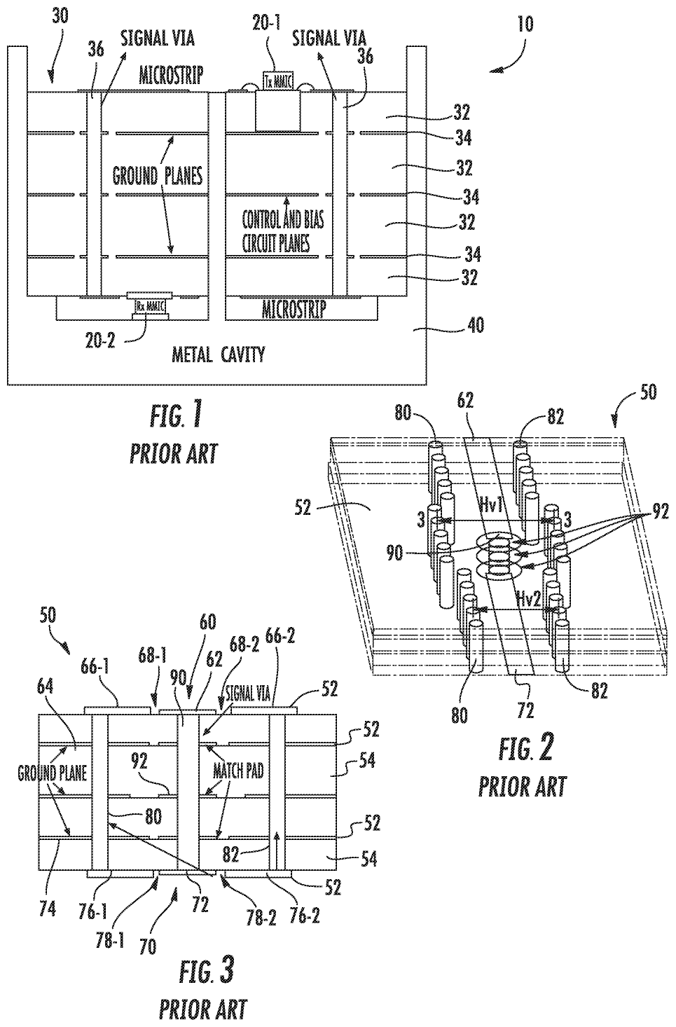

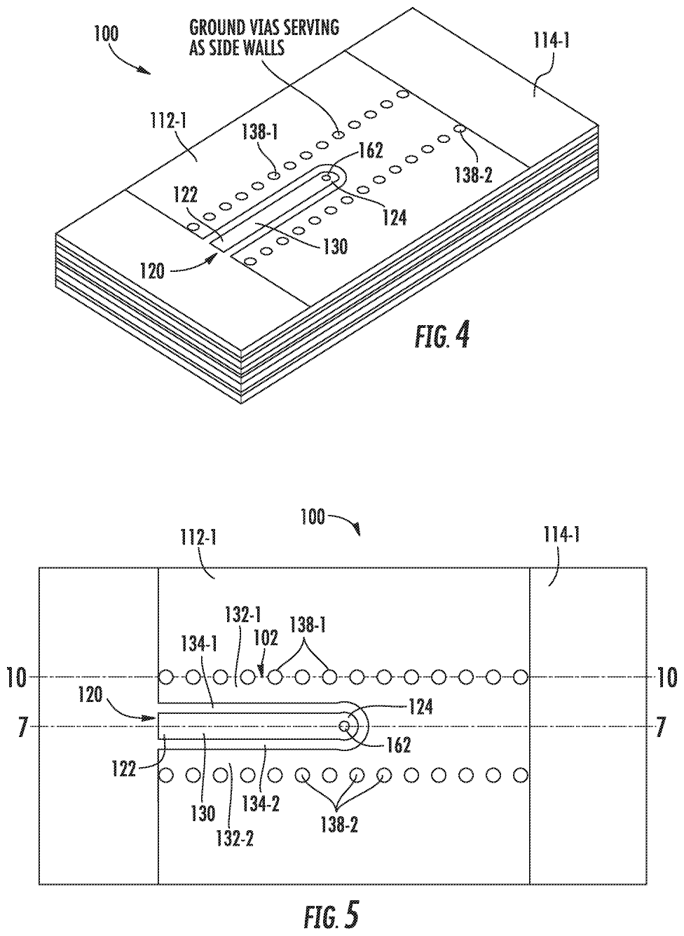

In this specification, like reference numerals will be used to refer to like elements. When multiple of the same element are included in certain of the embodiments disclosed herein, they may sometimes be referred to by two-part reference numerals (e.g., return conductors 66-1, 66-2). Such elements may be referred to individually by their full reference numeral (e.g., return conductor 66-2) and collectively by the first part of their reference numeral (e.g., the return conductors 66).

### DETAILED DESCRIPTION

Pursuant to embodiments of the present invention, system-in-package RF communications systems are provided in which a plurality of radiating elements are formed and/or are provided on a first side of a multi-layer printed circuit board structure and passive or active RF circuit components are formed on another layer or side of the printed circuit board structure. In order to interconnect the RF circuitry to the antenna array(s) in such systems, vertical transitions are formed through the printed circuit board structure to connect microstrip (or other) transmission lines on the opposed sides of the printed circuit board structure. At frequencies below about 3 GHz, such vertical transitions may readily be implemented using standard metal-plated vias that extend through the printed circuit board structure. However, at higher frequencies such as, for example, frequencies above 10-20 GHz, standard metal-plated vias may exhibit unacceptable voltage standing wave ratio and/or insertion loss performance.

Pursuant to embodiments of the present invention, vertical transitions for multi-layer printed circuit boards are provided that may be suitable for millimeter wave and other high frequency applications. The vertical transitions according to embodiments of the present invention may exhibit reduced losses and operate over wider bandwidths as compared to prior art vertical transitions. These vertical transitions may include one or more blind ground vias that may help reduce leakage of RF energy along RF leakage paths in the multi-layer substrate.

Pursuant to some embodiments of the present invention, RF transmission lines are provided in a multi-layer printed circuit board structure that include first and second rows of ground vias that extend vertically through the printed circuit board structure. A first transmission line segment extends horizontally along a first portion of the multi-layer printed circuit board structure and a second transmission line segment extends horizontally along a second portion of the multi-layer printed circuit board structure, the second transmission line segment vertically spaced apart from the first transmission line segment. A vertical dielectric structure extends between the first and second transmission line segments and at least one blind ground via extends vertically through the printed circuit board structure positioned adjacent the vertical dielectric structure.

Pursuant to further embodiments of the present invention, RF transmission lines are provided in a multi-layer printed circuit board structure. These RF transmission lines include a first transmission line segment that extends horizontally along a first portion of the multi-layer printed circuit board structure and a second transmission line segment that extends horizontally along a second portion of the multi-layer printed circuit board structure, the second transmission line segment vertically spaced apart from the first transmission line segment. A vertical dielectric structure extends between the first and second transmission line segments. A first ground via vertically overlaps the first transmission line segment and a second ground via vertically overlaps the second transmission line segment. The first and second ground vias may be blind ground vias.

Pursuant to still further embodiments of the present invention, RF transmission lines are provided in a multi-layer printed circuit board structure that include first and second rows of ground vias that extend vertically through the printed circuit board structure. A first transmission line segment extends horizontally along a first portion of the multi-layer printed circuit board structure and a second transmission line segment extends horizontally along a second portion of the multi-layer printed circuit board structure, the second transmission line segment vertically spaced apart from the first transmission line segment. A first blind ground via is provided adjacent the distal end of the first transmission line segment between the first and second rows of ground vias.

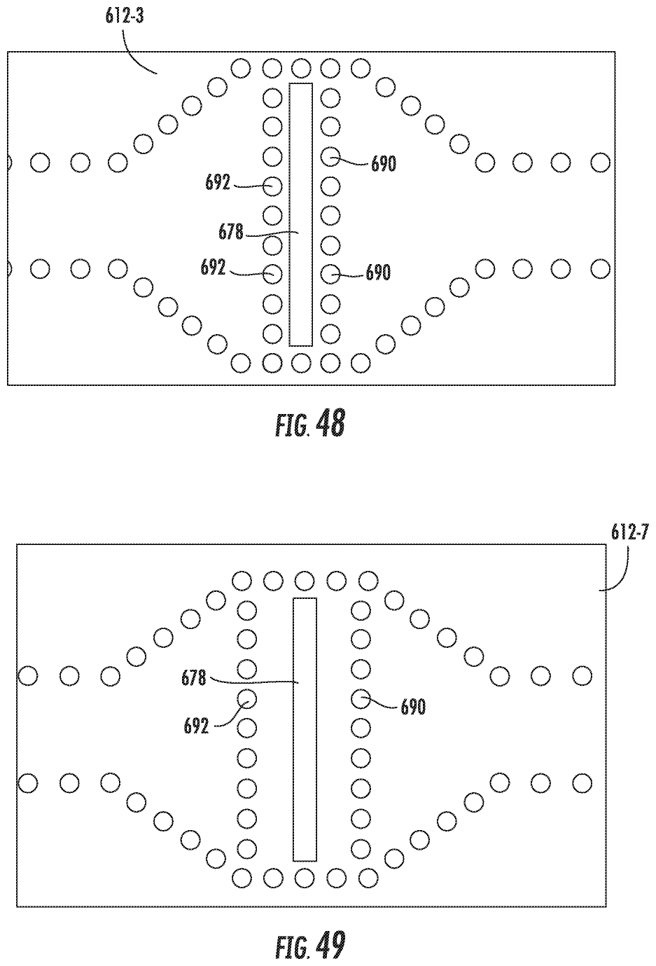

Embodiments of the present invention will now be discussed in further detail with reference to FIGS. 4-49.

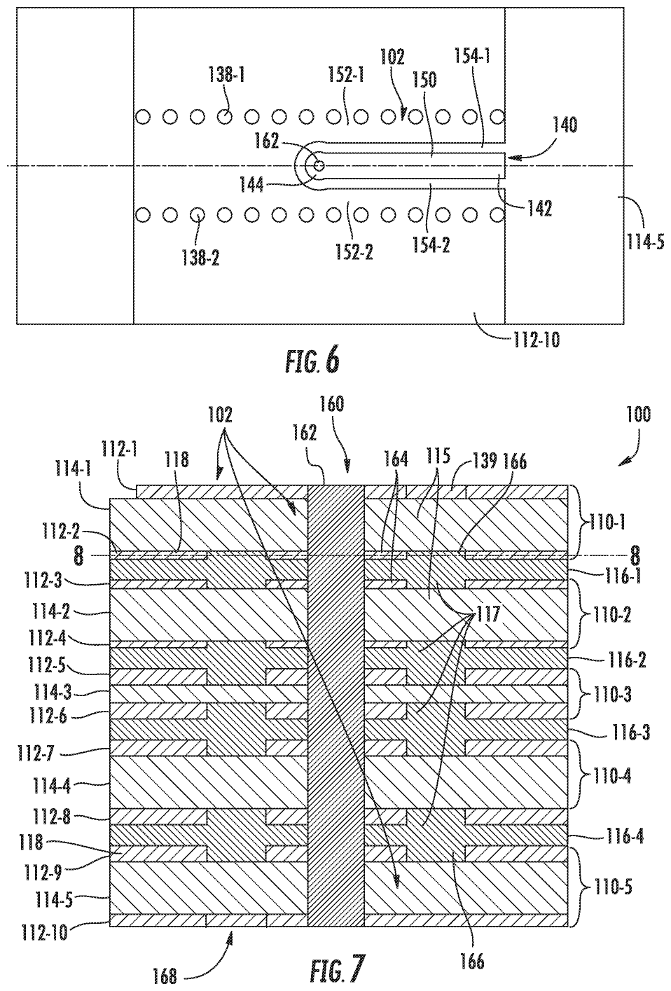

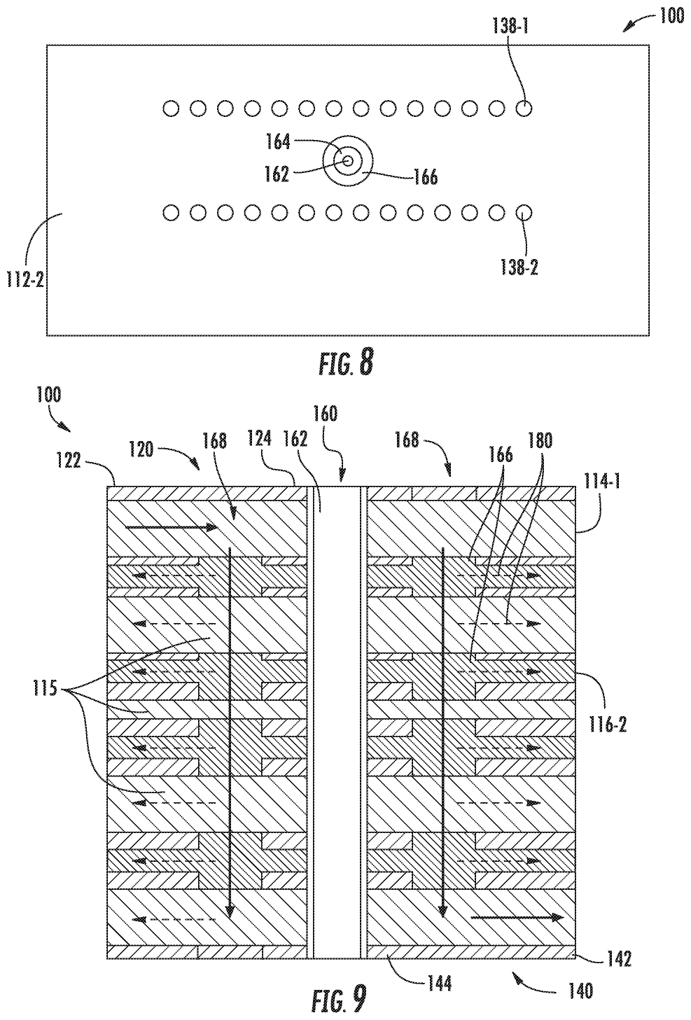

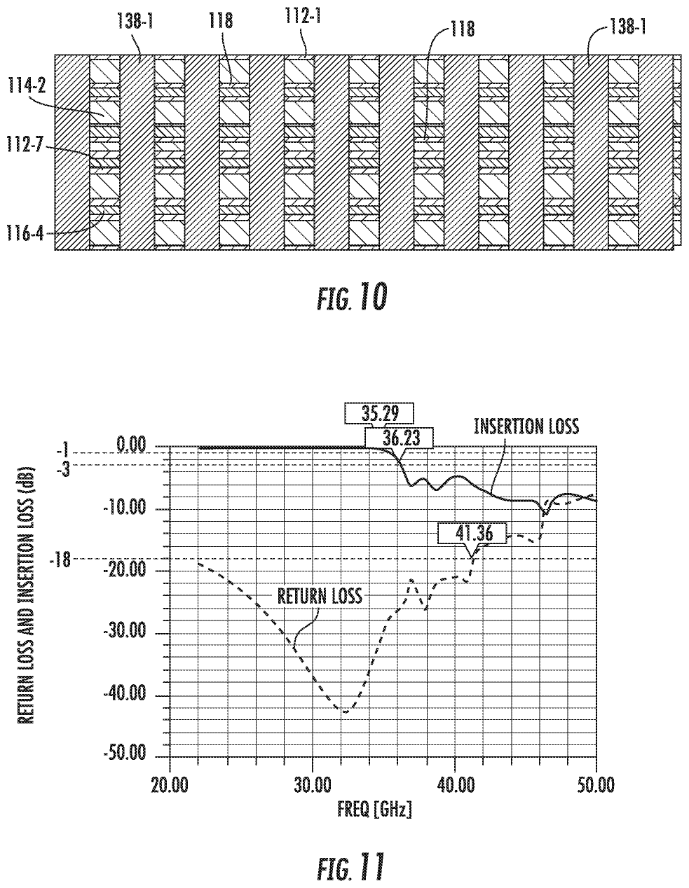

FIGS. 4-10 illustrate a portion of a printed circuit board structure 100 that may be used, for example, in a system-in-package RF communications system. The illustrated portion of the printed circuit board structure 100 includes an RF transmission line 102 that includes a vertical transition. FIG. 4 is a perspective view of the printed circuit board structure 100, while FIGS. 5 and 6 are plan top and bottom views, respectively, thereof. FIG. 7 is a vertical cross-sectional view taken along line 7-7 of FIG. 5, and FIG. 8 is a horizontal cross-section taken along line 8-8 of FIG. 7. FIG. 9 is a vertical cross-sectional view similar to FIG. 7 that illustrates RF leakage paths in the multi-layer printed circuit board structure 100. FIG. 10 is a vertical cross-sectional view taken along line 10-10 of FIG. 5. It will be appreciated from the discussion below that FIGS. 4-10 only show a small portion of the printed circuit board structure 100, namely a portion including the RF transmission line 102 that includes a first transmission line segment on the top layer of the printed circuit board structure 100 and a second transmission line segment on the bottom layer of the printed circuit board structure 100 that are physically and electrically connected to each other through a so-called “vertical transition.” Herein, the term “horizontal” refers to a direction that is parallel to a major surface of the multi-layer printed circuit board structures described herein and the term “vertical” refers to a direction that is perpendicular to a major surface of the multi-layer printed circuit board structures described herein.

Referring to FIGS. 4-10, the printed circuit board structure 100 is a multi-layer printed circuit board structure that includes a plurality of metal layers 112-1 through 112-10 and a plurality of core dielectric layers 114-1 through 114-5. A plurality of additional dielectric layers 116-1 through 116-4 are also provided. The dielectric layers 114, 116 separate the metal layers 112 from each other. The core dielectric layers 114 may comprise standard printed circuit board materials such as, for example, Taconic TSM-DS3, Arlon AD3003A, or Rogers RO3003 printed circuit board substrate materials. The metal layers 112 may be metal layers that are formed on the top and bottom surfaces of the core dielectric layers 114 using, for example, conventional printed circuit board fabrication techniques. Thus, a total of five so-called “double-layer” printed circuit boards 110 (i.e., printed circuit boards that comprise a core dielectric layer 114 with metal layers 112 on each side thereof) may be used to form the printed circuit board structure 100 of FIGS. 4-10.

As can best be seen in FIG. 7, each additional dielectric layer 116 is provided between two adjacent ones of the printed circuit boards 110. Each additional dielectric layer 116 may be used to adhere two printed circuit boards 110 together to create the laminated printed circuit board structure 100. The additional dielectric layers 116 may be formed using any suitable dielectric material such as, for example, a so-called “prepreg” material such as a fiberglass material or other composite fiber material that is pre-impregnated with a thermoset polymer matrix material (e.g., an epoxy resin). The composite fiber material may take the form of a weave. The epoxy resin (or other thermoset polymer matrix material) typically has adhesive properties, and a curing agent is included in the prepreg material. The prepreg material becomes flowable when heated and then acts as an adhesive to bind the fibers together and to other components such as the printed circuit boards 110.

As is further shown in FIG. 7, the metal layers 112 may be patterned metal layers that are not continuous layers, but instead have portions where no metal is present. Each patterned metal layer 112 may be formed, for example, by depositing a continuous metal layer on a surface (i.e., upper or lower) of the core dielectric layer 114, forming a mask on the continuous metal layer and then etching the continuous metal layer using the mask as an etch mask to form the patterned metal layer 112. While dielectric material may be filled into the openings in the patterned metal layers 112 in some embodiments, more typically the gaps are simply filled with air. When prepreg is used to form the additional dielectric layers 116, the prepreg material may be coated on one or both sides of the opposed patterned metal layers 112 of adjoining printed circuit boards 110 thereby filling in the openings in the patterned metal layers 112. The printed circuit boards 110 may be pressed together and heated to form the additional dielectric material layer 116 between the patterned metal layers 112 and within the openings in the patterned metal layers 112.

As can also be seen in FIG. 7, the portions 117 of the additional dielectric layers 116 that fill in the openings in the patterned metal layers 112 have an increased height in the vertical direction as compared to the remainder of each additional dielectric layer 116. These portions 117 of the additional dielectric layers 116 are referred to sometimes herein as “void rings” because they may have an annular or “ring” shape (see FIG. 8) and they fill in opposed, matching ring-shaped voids in the patterned metal layers 112.

Referring now to FIGS. 4-5 and 7, a first transmission line segment 120 extends horizontally along a portion of the multi-layer printed circuit board structure100. The first transmission line segment 120 is formed in the uppermost printed circuit board 110-1. The first transmission line segment 120 is implemented as a co-planar waveguide transmission line. The first transmission line segment 120 has a base end 122 and a distal end 124. The base end 122 may comprise, for example, a port that connects to a lead, cable, integrated circuit chip or the like or may comprise a connection to another transmission line. The distal end 124 is adjacent a vertical transition 160 (discussed below) that connects the first transmission line segment 120 to a second transmission line segment 140 implemented in another layer of the printed circuit board structure 100.

The first transmission line segment 120 includes a conductive track 130 that has return conductors 132-1, 132-2 disposed on either side thereof. Gaps 134-1, 134-2 in the metal layer 112-1 electrically separate the conductive track 130 from the respective return conductors 132-1, 132-2. The gaps 134-1, 134-2 may comprise air gaps in some embodiments, or may be filled in with a dielectric material. In the depicted embodiment a single, continuous U-shaped void in the patterned metal layer 112-1 forms both gaps 134-1, 134-2. A metal ground plane 118 is formed underneath the conductive track 130 in the metal layer 112-2 that is on the lower side of printed circuit board 110-1. Two rows of metal-plated or metal-filled vias 138-1, 138-2 (referred to collectively as “conductive vias”) connect the return conductors 132-1, 132-2 to the ground plane layer 118 on the opposite side of the core dielectric substrate 114-1. As shown, the rows of conductive vias 138 extend beyond the distal end of the first transmission line segment 120.

Referring now to FIGS. 4 and 6-7, a second transmission line segment 140 is formed in the lowermost printed circuit board 110-5. The second transmission line segment 140 is also implemented as a co-planar waveguide transmission line. The second transmission line segment 140 has a base end 142 and a distal end 144. The base end 142 may comprise, for example, a port that connects to a lead, cable, integrated circuit chip or the like or may comprise a connection to another transmission line. The distal end 144 is adjacent the vertical transition 160.

The second transmission line segment 140 includes a conductive track 150 that has return conductors 152-1, 152-2 disposed on either side thereof. Gaps 154-1, 154-2 in the metal layer 112-10 electrically separate the conductive track 150 from the respective return conductors 152-1, 152-2. The gaps 154-1, 154-2 may comprise air gaps in some embodiments, or may be filled in with a dielectric material. In the depicted embodiment a single, continuous U-shaped void in the patterned metal layer 112-10 forms both gaps 154-1, 154-2. A metal ground plane 118 is formed in the metal layer 112-9 that is on the upper side of printed circuit board 110-5. The two rows of conductive vias 138-1, 138-2 connect the return conductors 152-1, 152-2 to the ground plane layer 118 on the opposite side of the core dielectric substrate 114-5.

As shown in FIG. 7, the patterned metal layers 112-2 through 112-9 each include ground layer portions 118. The ground layer portions 118 are electrically connected to the conductive vias 138, as can best be seen in FIG. 10, and are also electrically connected to the return conductors 132, 152 of the respective first and second transmission line segments 120, 140. Each ground via 138 may extend through all of the patterned metal layers 112, core dielectric layers 114 and additional dielectric layers 116.

Referring to FIGS. 4-7, a vertical transition 160 connects the first transmission line segment 120 to the second transmission line segment 140. The vertical transition 160 includes a conductive signal via 162, a plurality of annular pads 164, and a plurality of annular void rings 166. The conductive signal via 162 extends vertically through the printed circuit board structure 100. The conductive signal via 162 may extend through all of the patterned metal layers 112, core dielectric layers 114 and additional dielectric layers 116. The top end of the conductive signal via 162 may be adjacent the distal end 124 of the first transmission line segment 120 and the bottom end of the conductive signal via 162 may be adjacent the distal end 144 of the second transmission line segment 140.

The annular pads 164 are part of the patterned metal layers 112-2 through 112-9. Each annular pad 164 surrounds the conductive signal via 162. The annular pads 164 are provided to facilitate formation of the conductive signal via 162, which may be formed by drilling a hole through the printed circuit board structure 100 and then plating the hole with metal. Each annular void ring 166 surrounds a pair of the annular pads 164. The annular void rings 166 are vertically stacked. As best shown in FIGS. 7 and 9, the void rings 166, along with the portions 115 of the core dielectric layers 114 that are vertically-aligned with the void rings 166, form an annular dielectric column 168. The annular dielectric column 168 acts to electrically isolate the conductive signal via 162 and the annular pads 164 from the ground pads 118.

The first transmission line segment 120, the second transmission line segment 140 and the vertical transition 160 form the RF transmission line 102. An RF signal may traverse the RF transmission line 102 as follows. RF energy is input at the base end 122 of the first transmission line segment 120. This RF energy flows along the first transmission line segment 120 to the distal end 124 thereof. The RF energy may primarily flow in the gaps 134-1, 134-2 that are formed between the conductive track 130 and the return conductors 132-1, 132-2 and in the region of the core dielectric layer 114-1 that is between (1) the first transmission line segment 120 and (2) the portion of the ground plane 118 in patterned metal layer 112-2 that is underneath the first transmission line segment 120. The ground vias 138 are spaced apart by less than a quarter wavelength. With this spacing, the ground vias 138 act as sidewalls of a waveguide structure and thus constrain the RF energy from travelling laterally beyond the ground vias 138.

FIG. 9 illustrates the RF energy flow through the vertical transition 160 of RF transmission line 102. As shown by the bold arrows in FIG. 9, in the vertical transition 160 section of the RF transmission line 102, the RF energy passes primarily through the annular dielectric column 168 formed by the void rings 166 and the portions 115 of the core dielectric substrates 114 therebetween. In particular, the RF energy passes from the base end 122 to the distal end 124 of the first RF transmission line segment 120, turns downwardly and passes through the annular dielectric column 168 to the distal end 144 of the second RF transmission line, and then travels over the second transmission line segment 140.

As further shown in FIG. 9, RF energy may also flow through the leakage paths 180 that are defined between adjacent ground pads 118. The adjacent ground pads 118 may appear as waveguides to the RF energy, facilitating such leakage. As shown in FIG. 9, the leakage paths 180 may be formed in both the core dielectric layers 114 and in the additional dielectric layers 116. This leakage of RF energy may degrade system performance.

FIG. 11 is a graph illustrating the return loss performance and insertion loss performance of the RF transmission line 102 that includes the first RF transmission line segment 120, the vertical transition 160 and the second RF transmission line segment 140. As shown in FIG. 11, return loss is less than −20 dB in the range from 22 GHz through about 41 GHz, but then quickly rises to −18 dB at 41.36 GHz and to −10 dB at about 46 GHz. Insertion loss is very low at frequencies below 35 GHz, but rises to 1 dB at 35.29 GHz and to 3 dB at 36.23 GHz.

The loss in RF energy that occurs as an RF signal traverses the RF transmission line 102 includes radiation loss and dissipation loss. The radiation loss refers to the total emission of electromagnetic energy, including laterally emitted radiation that flows in plate waveguide mode. The radiation loss may be defined as:

Radiation Loss=Radiated Power/Input Power (1)

The dissipation loss, which includes dielectric losses and metallic losses, may be defined as:

Dissipation Loss=Dissipated Power/Input Power (2)

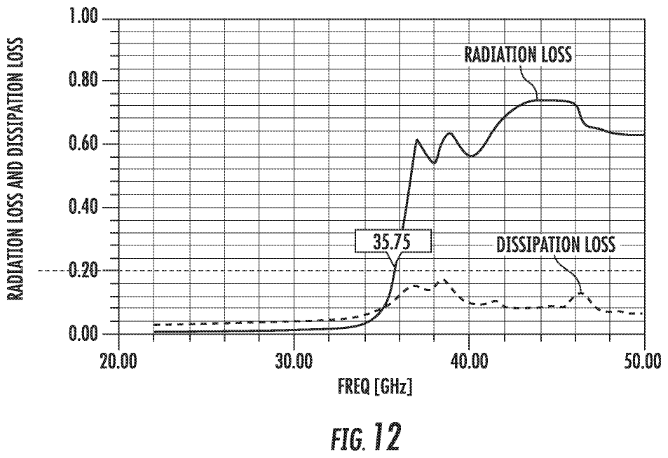

FIG. 12 is a graph illustrating the radiation loss (the solid curve) and the dissipation loss (the dashed curve) for the RF transmission line 102. As shown in FIG. 12, the radiation loss starts to increase at frequencies above about 30 GHz, rising to 20% of the total power at a frequency of 35.75 GHz. The dissipation loss also rises appreciably at about 34-35 GHz. Thus, FIGS. 11 and 12 show that the performance of the RF transmission line 102 starts to degrade appreciably at frequencies above about 34-36 GHz.

The radiation loss tends to increase with increasing thickness of the core dielectric layers 114 and/or the additional dielectric layers 116, as thicker dielectric layers may increase the size of radiation leakage paths. In some embodiments, the core dielectric layers have a thickness of 10 mils. Thinner core dielectric layers could be used to decrease the radiation loss, but this may increase the cost and/or create difficulties in the manufacturing processes. As such, switching to thinner dielectric layers 114, 116 may not be a viable option for reducing radiation losses.

Pursuant to embodiments of the present invention, RF transmission lines having vertical transitions are provided that may exhibit improved wideband performance. In some embodiments, the RF transmission lines may include one or more “blind” ground vias that may block some (or all) of the leakage paths 180 discussed above with reference to FIG. 9. Herein a “blind” via refers to a via that does not extend through all of the dielectric layers of a multi-layer printed circuit board structure. In some cases, the blind vias may be “buried” vias that do not extend through either the uppermost dielectric layer or the lowermost dielectric layer. In other cases, the blind vias may be “partially” blind vias that extend through one of, but not both, of the uppermost and lowermost dielectric layers.

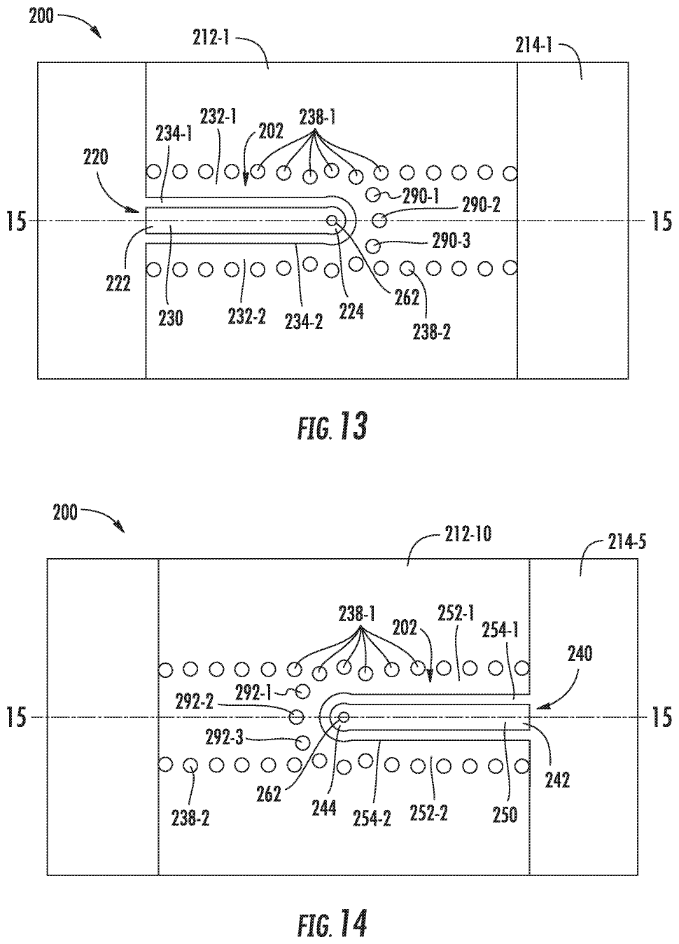

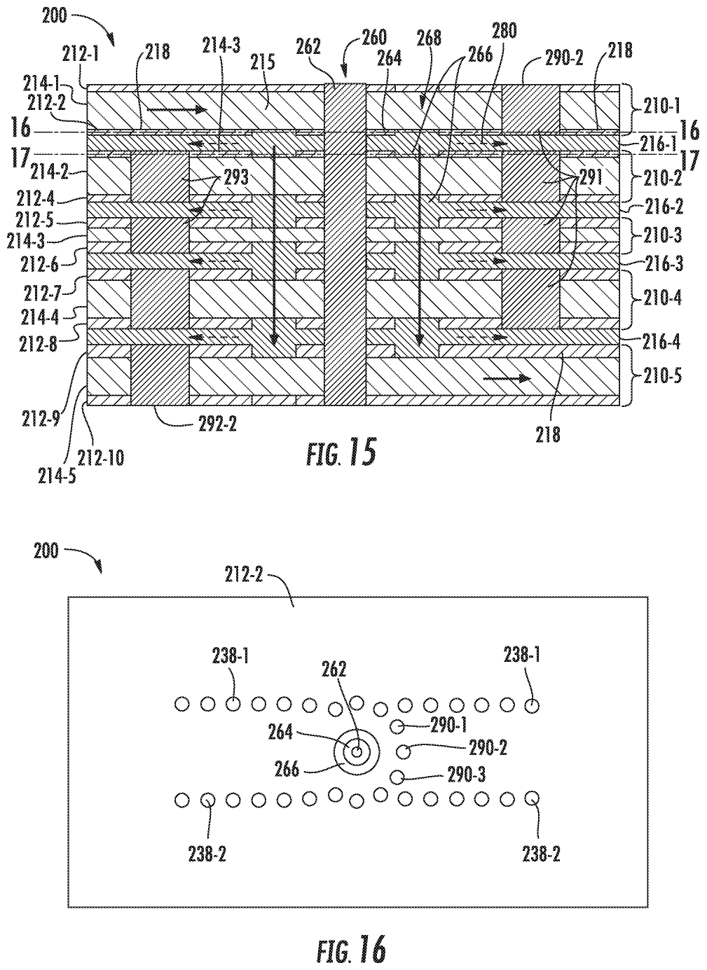

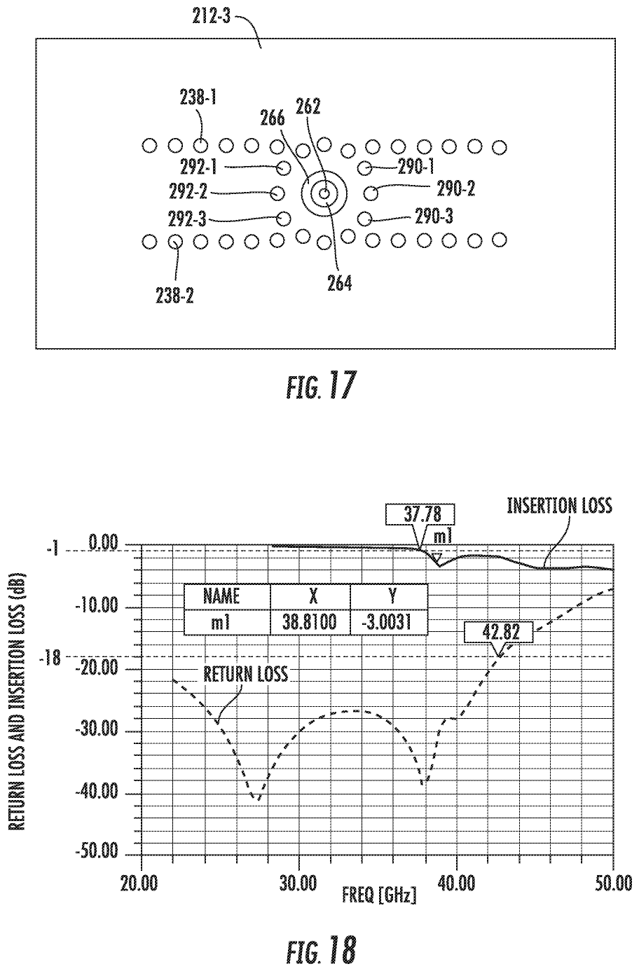

FIGS. 13-17 illustrate a portion of a printed circuit board structure 200 of a system-in-package RF communications system that includes an RF transmission line 202 that has a vertical transition 260. In particular, FIGS. 13 and 14 are plan top and bottom views, respectively, of the printed circuit board structure 200, and FIG. 15 is a vertical cross-sectional view taken along line 15-15 of FIG. 13. FIGS. 16 and 17 are horizontal cross-sectional views taken along lines 16-16 and 17-17, respectively, of FIG. 15.

Referring to FIGS. 13-17, the printed circuit board structure 200 includes a plurality of printed circuit boards 210-1 through 210-5 that may each include a pair of patterned metal layers 212 separated by a core dielectric layer 214. A total of ten patterned metal layers 212-1 through 212-10 and five core dielectric layers 214-1 through 214-5 are provided, and the printed circuit boards 210-1 through 210-5 are separated from each other by a plurality of additional dielectric layers 216-1 through 216-4. The printed circuit boards 210, the patterned metal layers 212, the core dielectric layers 214 and the additional dielectric layers 216 may be essentially identical to the printed circuit boards 110, patterned metal layers 112, core dielectric layers 114 and additional dielectric layers 116 that are described above and hence further description thereof will be omitted.

Metal layers 212-9 through 212-10 may be used for a variety of purposes. For example, various integrated circuit chips may be mounted on metal layer 212-10 and connected to elements on metal layer 212-1 using, for example, vertical transitions according to embodiments of the present invention. Patterned metal layers 212-2 and 212-9 may include ground planes that are part of the transmission line segments included on patterned metal layers 212-1 and 212-10, respectively, and may also include other elements. The intermediate patterned metal layers 212-2 through 212-9 may also be used as ground and/or power planes and as transmission paths for bias signals such as power signals, ground signals and/or control signals. Additionally, transmission paths for RF signals such as, for example, intermediate frequency signals, local oscillator signals and the like may also be provided on various of the intermediate patterned metal layers 212-2 through 212-9.

A first co-planar waveguide transmission line segment 220 is formed in the uppermost printed circuit board 210-1. The first transmission line segment 220 has a base end 222 and a distal end 224. The first transmission line segment 220 includes a conductive track 230 that has return conductors 232-1, 232-2 disposed on either side thereof. Gaps 234-1, 234-2 in the metal layer 212-1 electrically separate the conductive track 230 from the respective return conductors 232-1, 232-2. The gaps 234-1, 234-2 may comprise air gaps in some embodiments, or may be filled in with a dielectric material. A single, continuous U-shaped void in the patterned metal layer 212-1 forms both gaps 234-1, 234-2. A metal ground plane 218 is formed in the metal layer 212-2. Two rows of conductive vias 238-1, 238-2 connect the return conductors 232-1, 232-2 to the ground plane layer 218.

Referring to FIG. 14, a second co-planar waveguide transmission line segment 240 is formed in the lowermost printed circuit board 210-5. The second transmission line segment 240 has a base end 242 and a distal end 244. The second transmission line segment 240 includes a conductive track 250 that has return conductors 252-1, 252-2 disposed on either side thereof. Gaps 254-1, 254-2 in the metal layer 212-10 electrically separate the conductive track 250 from the respective return conductors 252-1, 252-2. The gaps 254-1, 254-2 may comprise air gaps in some embodiments, or may be filled in with a dielectric material. A single, continuous U-shaped void in the patterned metal layer 212-10 forms both gaps 254-1, 254-2. A metal ground plane 218 is formed in metal layer 212-9. The rows of ground vias 238-1, 238-2 connect the return conductors 252-1, 252-2 to the ground plane layer 218. Each ground via 238 may extend through all of the patterned metal layers 212, core dielectric layers 214 and additional dielectric layers 216. The patterned metal layers 212-2 through 212-9 each include ground layer portions 218.

As can also be seen in FIG. 15, a vertical transition 260 connects the first transmission line segment 220 to the second transmission line segment 240. The vertical transition 260 includes a conductive signal via 262, a plurality of annular pads 264, and a plurality of annular void rings 266. FIG. 16 illustrates the shape of the annular pads 264 and annular void rings 266. The conductive signal via 262 extends vertically through the printed circuit board structure 200. The top end of the conductive signal via 262 may be adjacent the distal end 224 of the first transmission line segment 220 and the bottom end of the conductive signal via 262 may be adjacent the distal end 244 of the second transmission line segment 240.

The annular void rings 266 are provided within the additional dielectric layers 216. The annular void rings 266 are vertically stacked. As shown in FIG. 15, the void rings 266, along with the portions 215 of the core dielectric layers 214 that are vertically-aligned with the void rings 266 form an annular dielectric column 268. The annular dielectric column 268 may serve as a vertical dielectric structure for RF energy travelling from the first transmission line segment 220 to the second transmission line segment 240. The annular dielectric column 268 also acts to electrically isolate the conductive signal via 262 and the annular pads 264 from the ground pads 218. The conductive signal via 262, the annular pads 264, and the annular void rings 266 may be identical to the conductive signal via 162, the annular pads 164, and the annular void rings 166 and hence further description thereof will be omitted.

The printed circuit board structure 200 further includes a plurality of discontinuous blind ground vias 290. Each discontinuous blind ground via 290 may be formed by forming conductive vias in the individual printed circuit boards 210 such that the conductive vias will be aligned with one another along a vertical axis when the individual printed circuit boards 210 are laminated together to form the printed circuit board structure 200. As shown in FIG. 15, the blind ground vias 290 are “discontinuous” in that they do not extend through the additional dielectric layers 216.

FIG. 15 illustrates two of the discontinuous blind ground vias 290, namely blind ground vias 290-2 and 292-2. Focusing on blind ground via 290-2, it can be seen that this blind ground via includes four discontinuous segments 291, each of which is formed through a respective one of the printed circuit boards 210-1 through 210-4. As a result, blind ground via 290-2 extends through patterned metal layers 212-1 though 212-8 and through core dielectric layers 214-1 though 214-4, but does not extend through any of the additional dielectric layers 216. As can be seen in FIG. 13, blind ground via 290-2 is part of a first set of blind ground vias 290 that are positioned above the second transmission line segment 240 adjacent the distal end 224 of the first transmission line segment 220. The first set of blind ground vias 290 includes the three blind ground vias 290-1 through 290-3 in this embodiment. The first set of blind ground vias 290 extend along vertical axes that define an arc that is transverse to a longitudinal axis of the first transmission line segment 220. Blind ground vias 290-1 and 290-3 may be identical to blind ground via 290-2.

A second set of blind ground vias 292 are positioned below the first transmission line segment 230 adjacent the distal end 224 of the first transmission line segment 220. The second set of blind ground vias 292 also includes three blind ground vias 292-1 through 292-3 in this embodiment. As can be seen in FIG. 15, blind ground via 292-2 includes four discontinuous segments 293, each of which is formed through a respective one of the printed circuit boards 210-2 through 210-5. As a result, blind ground via 292-2 extends through patterned metal layers 212-3 though 212-10 and through core dielectric layers 214-2 though 214-5, but does not extend through any of the additional dielectric layers 216. As can be seen in FIG. 14, blind ground vias 292-1 through 292-3 are positioned below the first transmission line segment 220 adjacent the distal end 244 of the second transmission line segment 240. The second set of blind ground vias 292 extend along vertical axes that define an arc that is transverse to a longitudinal axis of the second transmission line segment 240.

The blind ground vias 290, 292 create ground walls that reduce or eliminate leakage of RF energy through some of the leakage paths 180 that are discussed above with reference to FIGS. 4-10.

FIG. 15 illustrates the RF energy flow through the RF transmission line 202 including the vertical transition 260. As shown in FIG. 15, the RF energy passes primarily through the annular dielectric column 268 formed by the void rings 266 and the portions 215 of the core dielectric substrates 214 therebetween. In particular, the RF energy passes from the base end 222 to the distal end 224 of the first transmission line segment 220, turns downwardly and passes through the annular dielectric column 268 to the distal end 244 of the second transmission line segment 240, and then travels over the second transmission line segment 240.

FIG. 15 also illustrates how the blind ground vias 290, 292 block leakage of RF energy. As discussed above with reference to FIG. 7, RF energy (represented by the dashed arrows 180 in FIGS. 7 and 280 in FIG. 15) will tend to leak along the core dielectric layers 214 and the additional dielectric layers 216 because the ground plates 218 included in the patterned metal layers 212 surrounding each dielectric layer 214, 216 appear as waveguides. The blind ground vias 290, 292 create respective ground walls that block leakage of RF energy through the core dielectric layers 214. Leakage may still occur through the additional dielectric layers 216 since the discontinuous blind ground vias 290, 292 do not extend through the additional dielectric layers 216. FIG. 17 shows how in the interior of the printed circuit board structure 200 (e.g., between patterned metal layers 212-3 through 212-8) the first and second sets of blind ground vias 290, 292 essentially surround the conductive signal via 262 to reduce leakage currents along horizontal paths. The blind ground vias 290, 292 in each of the first and second sets may be spaced apart by less than a quarter wavelength. With this spacing, the blind ground vias 290, 292 act as sidewalls of a waveguide structure and thus constrain the RF energy from travelling laterally beyond the blind ground vias 290, 292.

In the printed circuit board structure 200, a large portion of the RF leakage energy is blocked by the blind ground vias 290, 292. This can be seen by comparing the return loss and insertion loss performance of RF transmission line 202, which is shown in FIG. 18 to the return loss and insertion loss performance of RF transmission line 102 shown in FIG. 11.

In particular, as can be seen in FIG. 18, the −18 dB return loss bandwidth for the RF transmission line 202 is 42.82 GHz as compared to 41.36 GHz (see FIG. 11) for RF transmission line 102. Likewise, the −1 dB insertion loss bandwidth is extended to 37.78 GHz as compared to 35.29 GHz for the printed circuit board structure 100. Thus, the printed circuit board structure 200 provides about a 1.5 GHz improvement in the operating bandwidth as compared to printed circuit board structure 100.

Likewise, FIG. 19 is a graph illustrating the radiation loss and the dissipation loss for the RF transmission line 202. As shown in FIG. 19, the radiation loss reaches 20% at a frequency of 38.20 GHz, which is almost 2.5 GHz higher than the frequency at which radiation losses reach 20% in the printed circuit board structure 100 (see FIG. 12).

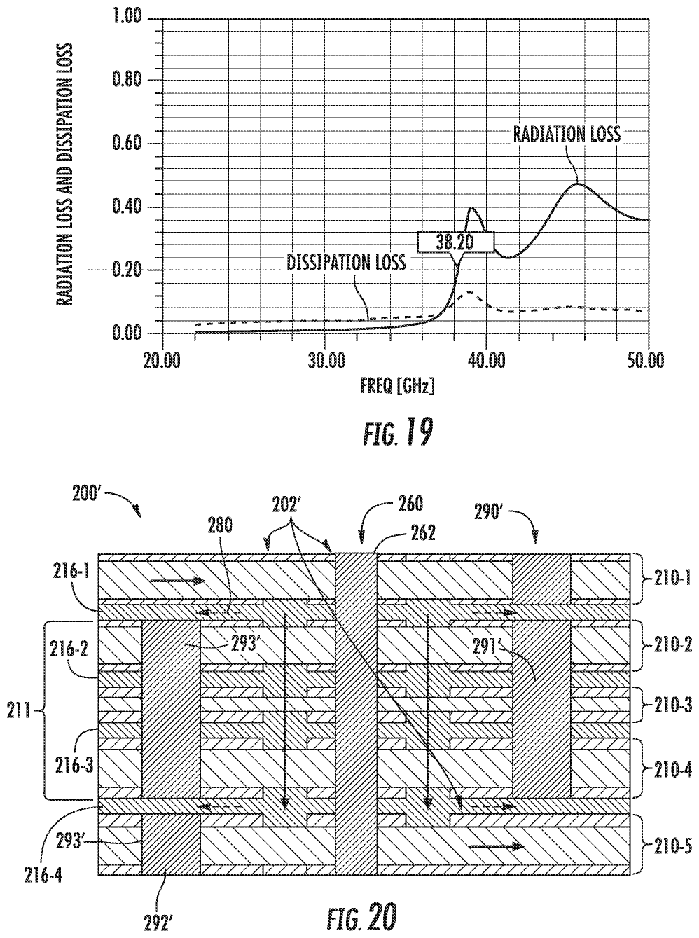

FIG. 20 is a vertical cross-sectional view of a modified version 200′ of the printed circuit board structure 200 of FIGS. 13-17. The printed circuit board structure 200′ has top, bottom and horizontal cross-sections that are identical to the corresponding views shown in FIGS. 13-14 and 17, respectively for printed circuit board structure 200. A comparison of FIGS. 15 and 20 illustrates the differences between the two printed circuit board structures 200, 200′.

The printed circuit board structure 200′ has an RF transmission line 202′ that includes a vertical transition 260 formed therein. As can be seen by comparing FIGS. 15 and 20, in the printed circuit board structure 200′, the blind ground vias 290′, 292′ extend through some of the additional dielectric layers 216. In particular, the blind ground vias 290′, 292′ extend through additional dielectric layers 216-2 and 216-3. Thus, the printed circuit board structure 200′ blocks additional of the RF leakage paths 280 as compared to the printed circuit board structure 200.

The printed circuit board structure 200′ may be fabricated as follows. Printed circuit boards 210-2 through 210-4 may be fabricated and laminated together to form an intermediate structure 211. Then, holes for the blind ground vias 290′, 292′ may be drilled or otherwise formed through the intermediate structure 211, and these holes may be plated and/or filled with metal to form the portion of each blind ground via 290′, 292′ that will be buried within the printed circuit board structure 200′. Before or after this step, printed circuit boards 210-1 and 210-5 may be formed to include the conductive vias that will form the remainder of each blind ground via 290′, 292′. Printed circuit boards 210-1 and 210-5 may then be laminated onto the intermediate structure 211. Finally, the conductive signal via 262 (including the plated sidewalls thereof) may be formed to complete the printed circuit board structure 200′. The resulting structure has blind ground vias 290′ that each have two segments 291′ and blind ground vias 292′ that each have two segments 293′.

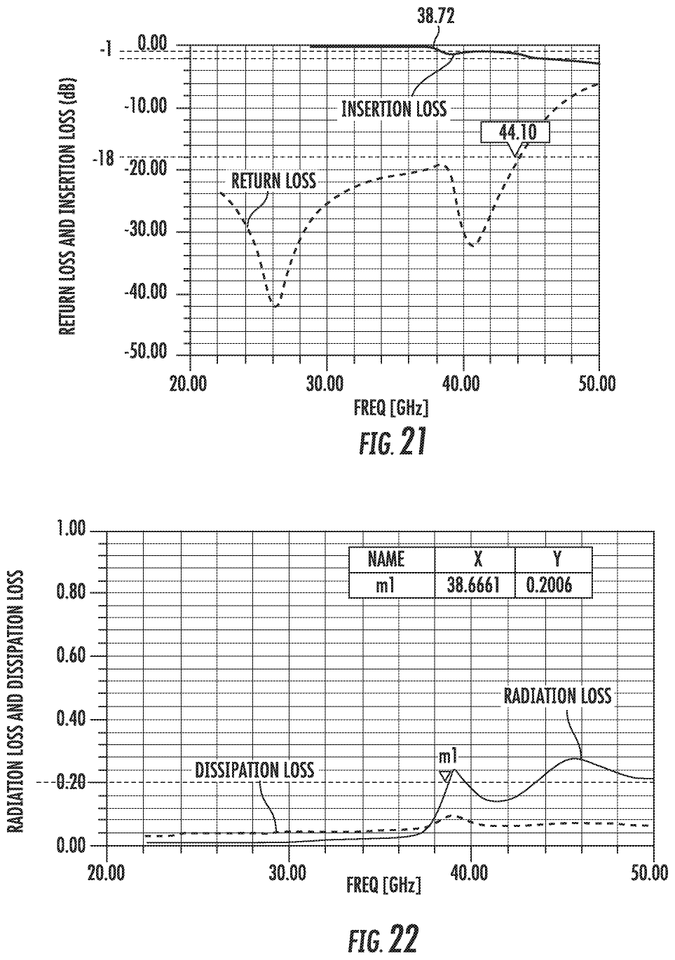

FIG. 21 is a graph illustrating the return loss and insertion loss performance for the RF transmission line 202′ included on the modified printed circuit board structure 200′ FIG. 22 is a graph illustrating the radiation loss and the dissipation loss for the RF transmission line 202′.

As can be seen by comparing FIGS. 21-22 to FIGS. 18-19, the −18 dB return loss bandwidth for the RF transmission line 202′ extends out to 44.10 GHz, which is an improvement of more than 1.25 GHz as compared to the RF transmission line 202. Likewise, the −1 dB insertion loss bandwidth for the RF transmission line 202′ extends out to 38.72 GHz, which is an improvement of almost 1 GHz as compared to the RF transmission line 202. As shown in FIG. 22, the radiation loss for the RF transmission line 202′ does not reach 20% until 38.67 GHz, which is an improvement of almost 0.5 GHz as compared to the RF transmission line 202.

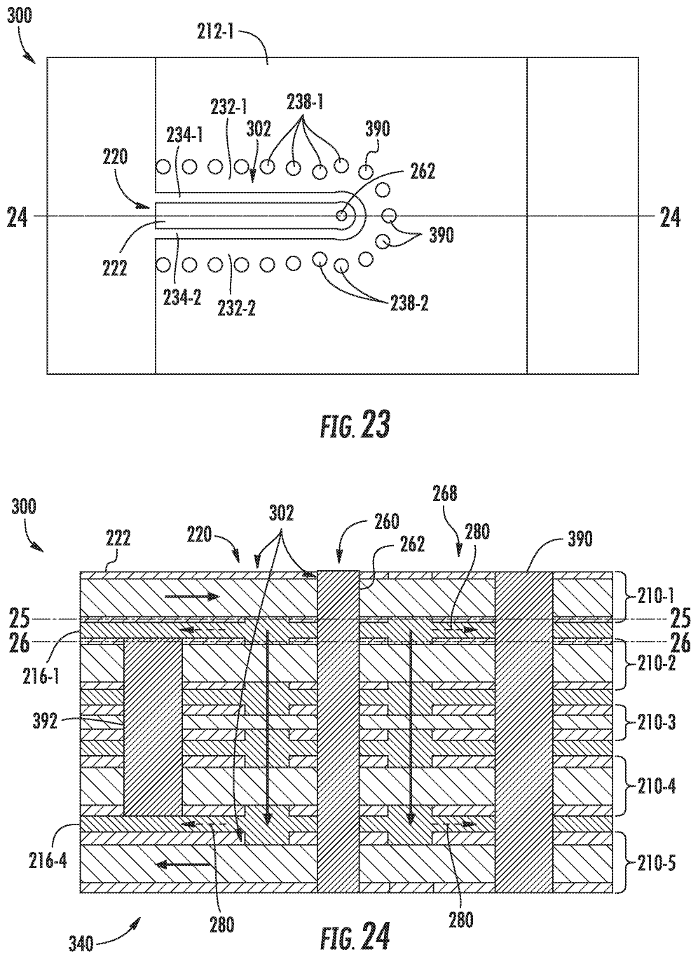

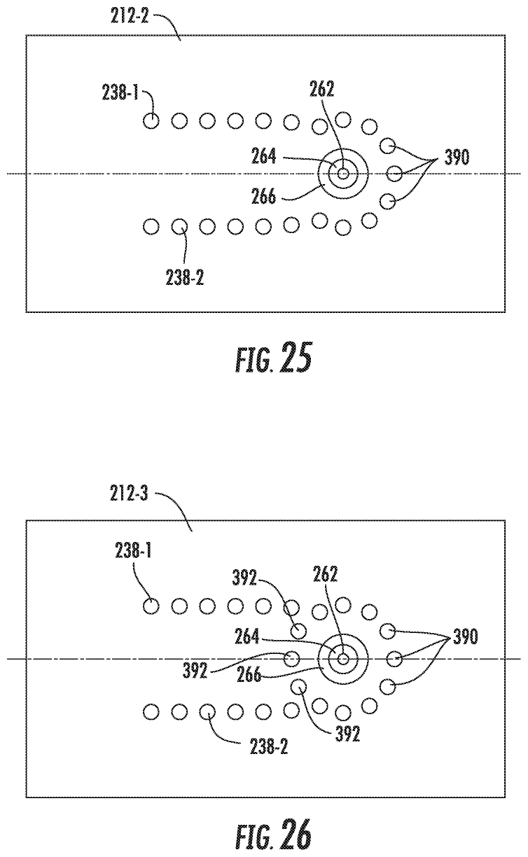

FIGS. 23-26 illustrate a printed circuit board structure 300 having an RF transmission line 302 with a vertical transition 360 according to further embodiments of the present invention. In particular, FIG. 23 is a plan top view of the printed circuit board structure 300, while FIG. 24 is a vertical cross-sectional view taken along line 24-24 of FIG. 23. FIGS. 25 and 26 are horizontal cross-sections taken along lines 25-25 and 26-26, respectively, of FIG. 24. In the embodiment of FIGS. 23-26, the first and second transmission line segments that are connected by the vertical transition extend on the same side of the vertical transition (and in this case are vertically overlapping). The elements of the printed circuit board structure 300 that are the same as elements of printed circuit board structure 200 have identical reference numerals and the discussion below will thus focus on the elements of printed circuit board structure 300 that differ from the corresponding elements of printed circuit board structure 200.

Referring to FIGS. 23 and 24, it can be seen that the second RF transmission line segment 340 extends in a different direction than the second RF transmission line segment 240 of printed circuit board structure 200. In particular, the second RF transmission line segment 340 extends from the conductive signal via 262 back towards the base 222 of the first RF transmission line 220, albeit on a different layer of the printed circuit board structure 300. This change in the routing of the RF transmission line formed 302 formed by RF transmission line segments 220, 340 and the vertical transition 260 results in corresponding changes to the blind ground vias 290, 292 of printed circuit board structure 200.

In particular, as shown in FIG. 24, a plurality of “through ground vias” 390 are provided to the right of the conductive signal via 262 of the vertical transition 260. The through ground vias 390 are similar to the blind ground vias 290, 292 except that they extend all the way through the printed circuit board structure 300 (i.e., from top surface to bottom surface) and hence are not “blind” ground vias. The through ground vias 390 may block RF leakage energy. Through ground vias 390 may be used since the second transmission line segment 340 does not extend to the right of the conductive signal via 262. As can be seen, in FIG. 24, the through ground vias 390 may effectively block all of the RF leakage paths 280 to the right of the conductive signal via 262 since the through vias 390 extend through all of the dielectric layers 214, 216.

Referring to FIGS. 24 and 26, it can be seen that a plurality of buried blind ground vias 392 are provided between the first transmission line segment 220 and the second transmission line segment 340. Each buried blind ground via 392 may extend through the layers of printed circuit boards 210-2 through 210-4. The buried blind ground vias 392 may be formed in the same fashion as the buried portions of the blind vias included in printed circuit board structure 200′ (i.e., by forming the intermediate structure 211 and then forming ground vias through the intermediate structure 211).

As can be seen in FIG. 24, the through ground vias 390 may block all of the RF leakage paths 280 to the right of the conductive signal via 262, and the buried blind ground vias 392 may block all of the RF leakage paths to the left of the conductive signal via except for the RF leakage paths 280 in additional dielectric layers 216-1 and 216-4. It is anticipated that printed circuit board structure 300 will exhibit improved performance as compared to printed circuit board structure 200′ since additional of the RF leakage paths 280 are blocked in the printed circuit board structure 300.

The example embodiments discussed above include transmission line segments (e.g., transmission line segments 220, 240) that are implemented as co-planar waveguide RF transmission line segments. Pursuant to further embodiments of the present invention, blind ground vias may be used to improve the performance of RF transmission lines having vertical transitions that are implemented with substrate integrated waveguide transmission line segments.

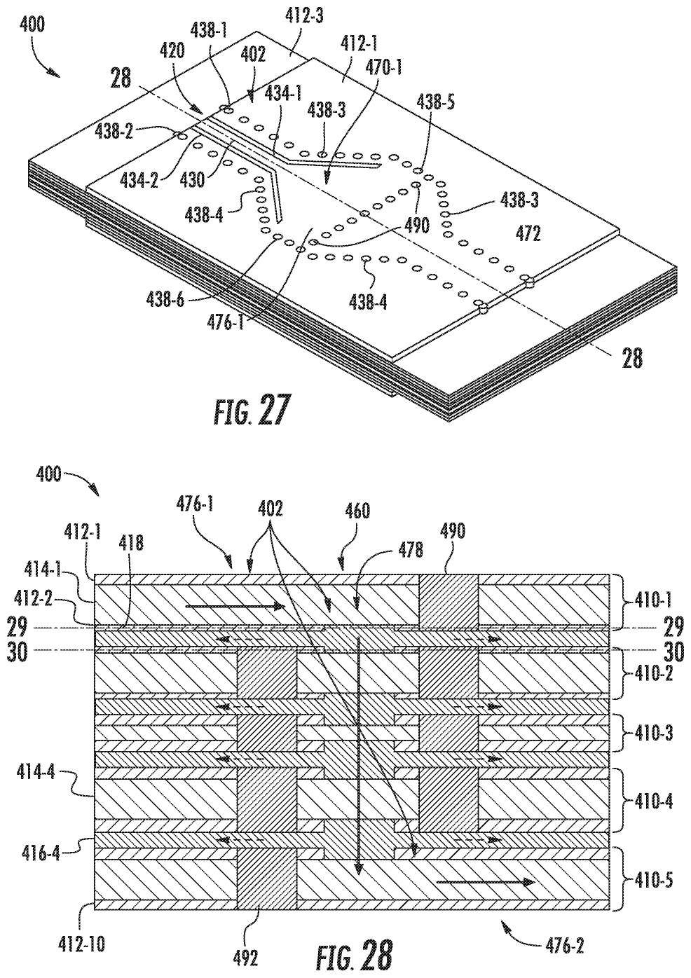

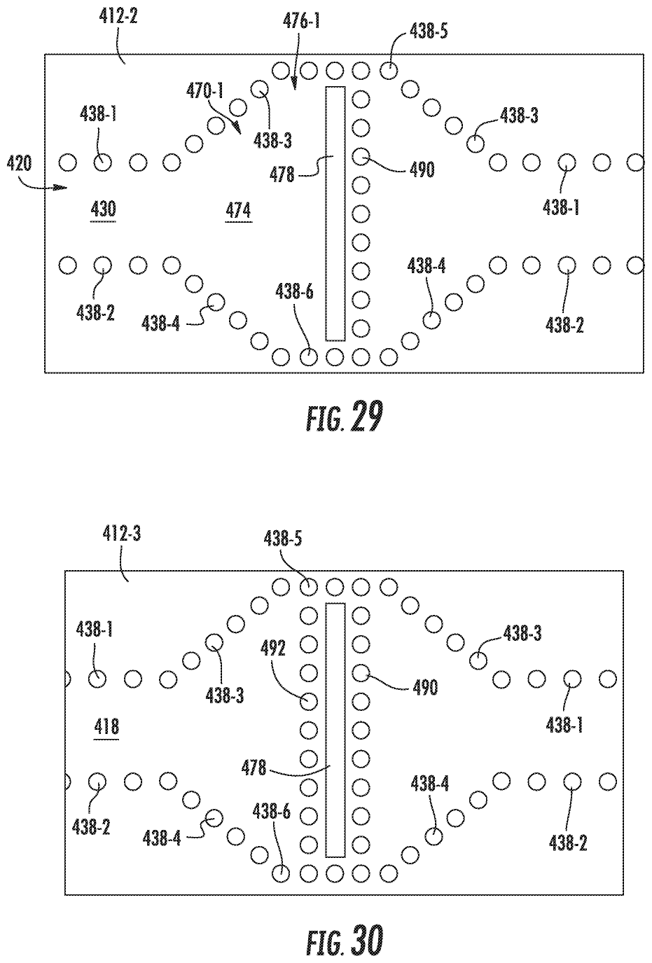

FIGS. 27-30 illustrate a printed circuit board structure 400 according to further embodiments of the present invention. In particular, FIG. 27 is a perspective view of the printed circuit board structure 400, and FIG. 28 is a vertical cross-sectional view taken along line 28-28 of FIG. 27. FIGS. 29 and 30 are horizontal cross-sections taken along line 29-29 and 30-30, respectively, of FIG. 28.

The printed circuit board structure 400 may be part of a system-in-package RF communications system. The printed circuit board structure 400 includes an RF transmission line 402 that has a vertical transition 460 that connects a first RF transmission line segment 420 implemented in a first printed circuit board 410-1 to a second RF transmission line segment 440 that is implemented in a second, different, printed circuit board 410-5. As with the previously described embodiments, the figures only show the portion of the printed circuit board structure 400 that includes the vertical transition 460.

The printed circuit board structure 400 includes an RF transmission line 402 that includes a first co-planar waveguide RF transmission line segment 420, a first co-planar waveguide to substrate integrated waveguide transition 470-1, a first substrate integrated waveguide transmission line segment 476-1, a vertical transition 460, a second substrate integrated waveguide transmission line segment 476-2, a second co-planar waveguide to substrate integrated waveguide transition 470-2, and a second co-planar waveguide RF transmission line segment 440. The first and second co-planar waveguide RF transmission line segments 420, 440 may be identical to the first and second co-planar waveguide RF transmission line segments 220, 240, and hence further description thereof will be omitted.

A substrate integrated waveguide refers to a waveguide structure that is formed in a multi-layer substrate such as a printed circuit board that includes a dielectric substrate with metal layers on opposed surfaces thereof. A substrate integrated waveguide includes upper and lower metal layers that are formed on the dielectric substrate and two rows of conductive posts (e.g., metal-plated or metal-filled posts). Each metal post may connect the upper metal layer to the lower metal layer. The combination of the two metal layers and the two rows of metal posts define waveguide structure in the dielectric substrate that RF signals may be transmitted through.

As shown in FIG. 27, the first co-planar waveguide to substrate integrated waveguide transition 470-1 is formed in the top printed circuit board 410-1 of the printed circuit board structure 400. The top printed circuit board 410-1 includes a first patterned metal layer 412-1, a core dielectric layer 414-1 and a second patterned metal layer 412-2 (see FIG. 28). The first co-planar waveguide to substrate integrated waveguide transition 470-1 is formed by providing third and fourth rows of ground vias 438-3, 438-4 that angle outwardly from the respective first and second rows of ground vias 438-1, 438-2 of the first co-planar waveguide structure 420. The third row of ground vias 438-3 connects the first row of ground vias 438-1 to a fifth row of ground vias 438-5 that defines a first sidewall of the first substrate integrated waveguide transmission line segment 476-1. The fourth row of ground vias 438-4 connects the second row of ground vias 438-2 to a sixth row of ground vias 438-6 that defines the second sidewall of the first substrate integrated waveguide transmission line segment 476-1. The first co-planar waveguide to substrate integrated waveguide transition 470-1 further includes a top metal layer 472 that is part of the first patterned metal layer 412-1 and a bottom metal layer 474 that is part of the second patterned metal layer 412-2. The top metal layer 472 connects to the conductive track 430 of the first co-planar waveguide structure 420. The bottom metal layer 474 is continuous with the ground plane 418 of the first co-planar waveguide structure 420. The gaps 434-1, 434-2 of the first co-planar waveguide structure 420 angle outwardly through the first co-planar waveguide to substrate integrated waveguide transition 470-1 (see FIG. 27). The second co-planar waveguide to substrate integrated waveguide transition 470-2 may be identical to the first co-planar waveguide to substrate integrated waveguide transition 470-1 except that it is implemented in printed circuit board 410-5 and hence further description thereof will be omitted.

An RF signal input to the first co-planar waveguide transmission line 420 passes to the first co-planar waveguide to substrate integrated waveguide transition 470-1 which spreads the RF energy out laterally in order to inject the RF signal into the substrate integrated waveguide transmission line segment 476-1. Energy then passes through the substrate integrated waveguide transmission line segment 476-1. In order to simplify the figures, the first and second substrate integrated waveguide transmission line segments 476-1, 476-2 are depicted in the figures as being very short waveguide segments.

As shown best in FIGS. 28 and 29, a dielectric slot 478 is formed in the printed circuit board structure 400 at the end of the first substrate integrated waveguide transmission line segment 476-1. The dielectric slot 478 may comprise a vertically extending column of dielectric material that extends between core dielectric layer 414-1 and core dielectric layer 414-5. The dielectric slot 478 may have, for example, a rectangular horizontal cross-section in some embodiments. The dielectric slot 478 may be formed through the core dielectric layers 414 and the additional dielectric layers 416.

A first row of blind ground vias 490 are formed to the right of the dielectric slot 478. The blind ground vias 490 may have same structure as the blind ground vias 290 described above with reference to FIGS. 13-17. An RF signal traversing the first substrate integrated waveguide transmission line segment 476-1 is blocked by the row of blind ground vias 490, and thus turns downwardly to propagate through the dielectric slot 478. As described above with reference to printed circuit board structures 100 and 200, a plurality of leakage paths 480 exist in the printed circuit board structure 400. A second row of blind ground vias 492 is also provided that has the same structure as the blind ground vias 292 described above with reference to FIGS. 13-17. The first and second rows of blind ground vias 490, 492 block the RF leakage paths 480 through the core dielectric layers 414 of printed circuit board structure 400. This approach may more efficiently channel the RF signal between the first substrate integrated waveguide transmission line segment 476-1 and the second substrate integrated waveguide transmission line segment 476-2. The second substrate integrated waveguide transmission line segment 476-2 may be identical to the first substrate integrated waveguide transmission line segment 476-1 discussed above, except that it is implemented in the fifth printed circuit board 410-5.

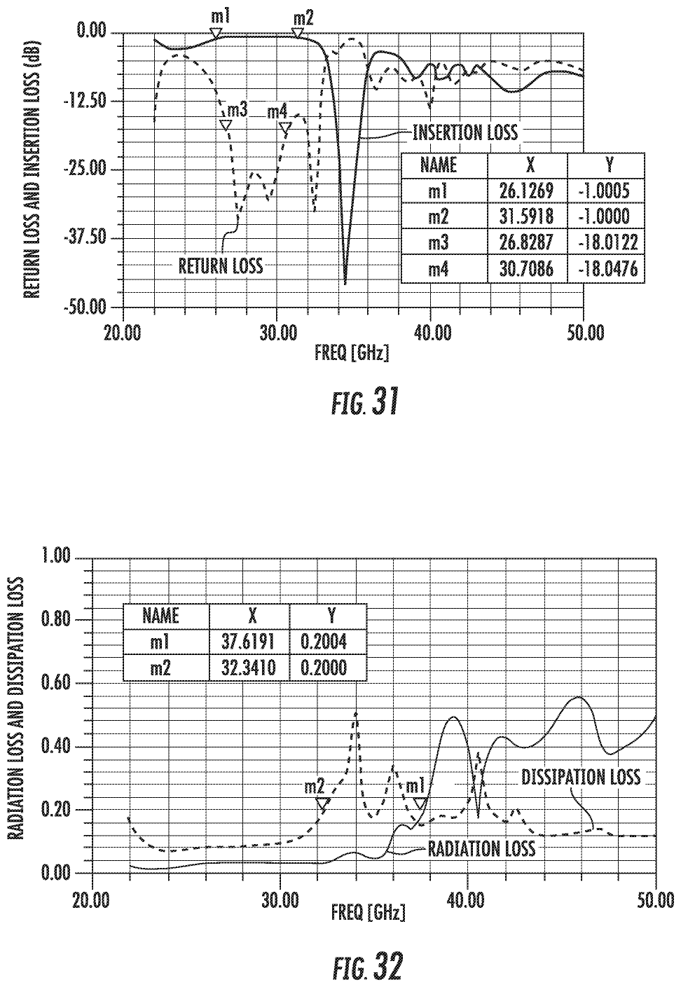

FIG. 31 is a graph illustrating the return loss performance and the insertion loss performance of the RF transmission line 402. As shown in FIG. 31, the −18 dB return loss bandwidth extends from 26.83 GHz to 30.70 GHz, and the −1 dB insertion loss bandwidth extends from 26.13 GHz to 31.59 GHz. FIG. 32 illustrates the radiation loss and dissipation loss performance for the RF transmission line 402. The radiation loss exceeds 20% at 32.34 GHz.

FIG. 33 is a vertical cross-sectional view of a modified version 400′ of the printed circuit board structure 400 of FIGS. 27-30. The printed circuit board structure 400′ is similar to printed circuit board structure 400, with the primary difference being that the blind ground vias 490′, 492′ included in printed circuit board structure 400′ extend continuously through the printed circuit boards 410-2 through 410-4. Thus, the embodiment of FIG. 33 is the counterpart to the embodiment of FIG. 28 for the RF transmission line 402. The blind ground vias 490′, 492′ may be fabricated in the same manner (discussed above) as blind ground vias 290′, 292′.

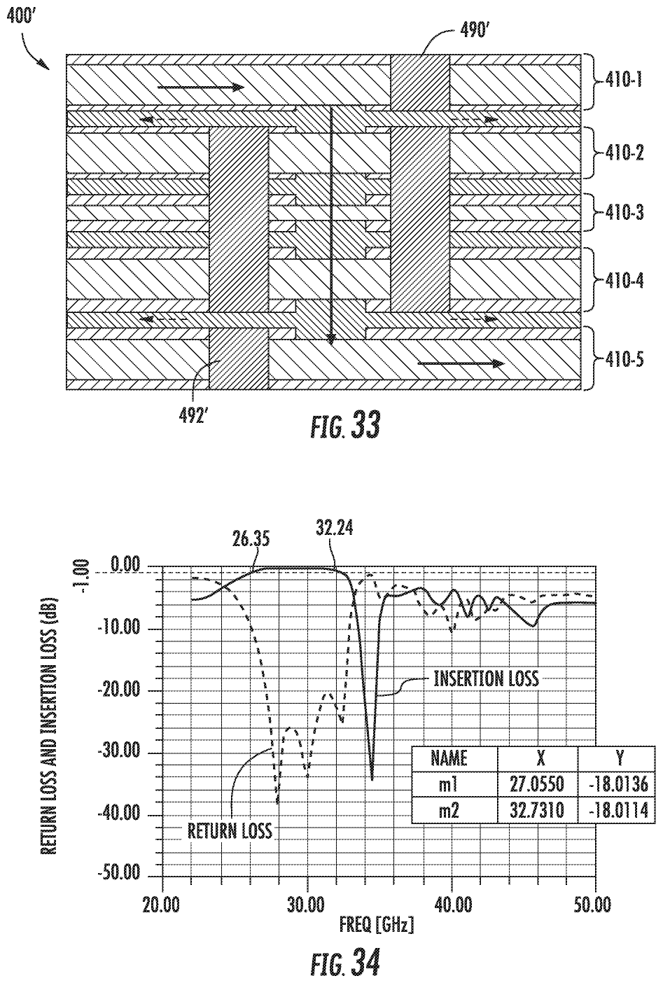

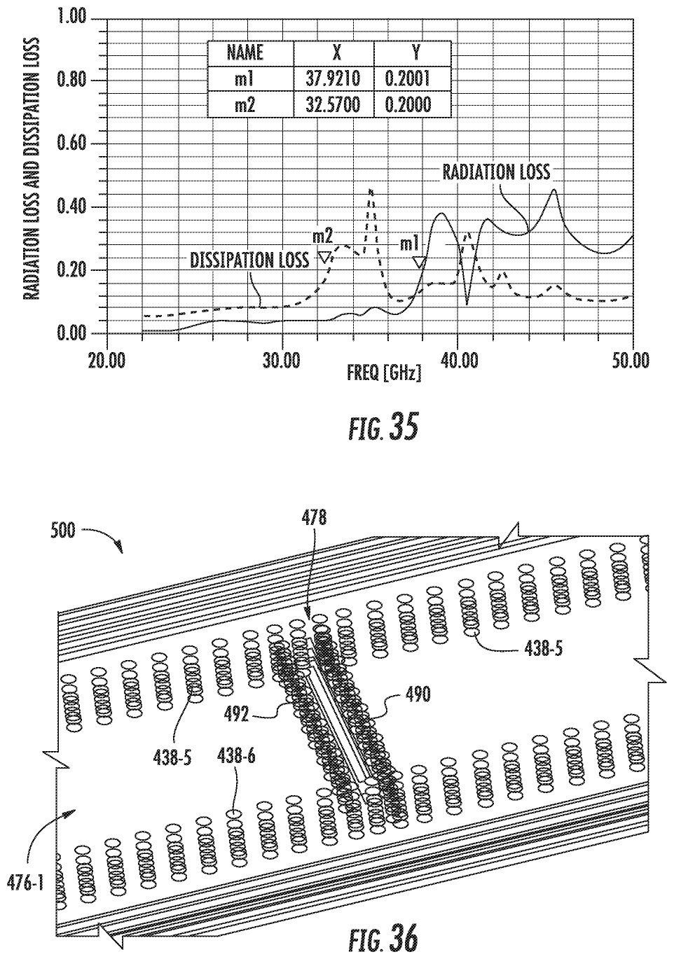

FIG. 34 is a graph illustrating the return loss and insertion loss performance for the RF transmission line of FIG. 33. FIG. 35 is a graph illustrating the radiation loss and the dissipation loss for the RF transmission line 402′.

As can be seen by comparing FIGS. 34-35 to FIGS. 31-32, the −18 dB return loss bandwidth for the RF transmission line 402′ is widened (as compared to RF transmission line 402) to extend from 27.06 to 32.73, and the −1 dB insertion loss bandwidth is widened to extend from 26.35 GHz to 32.24 GHz. Likewise, FIG. 34 shows that the radiation loss does not reach 20% until a frequency of 32.57 GHz.

FIGS. 27-30 and 33 illustrate two example embodiments in which blind ground vias are used to improve the performance of RF transmission lines that include both co-planar waveguide and substrate integrated waveguide transmission line segments. It will be appreciated, however, that the exact same techniques may be used to form vertical transitions in RF transmission lines that are formed simply of first and second substrate integrated waveguide segments that are implemented on different layers of a multi-layer printed circuit board structure.

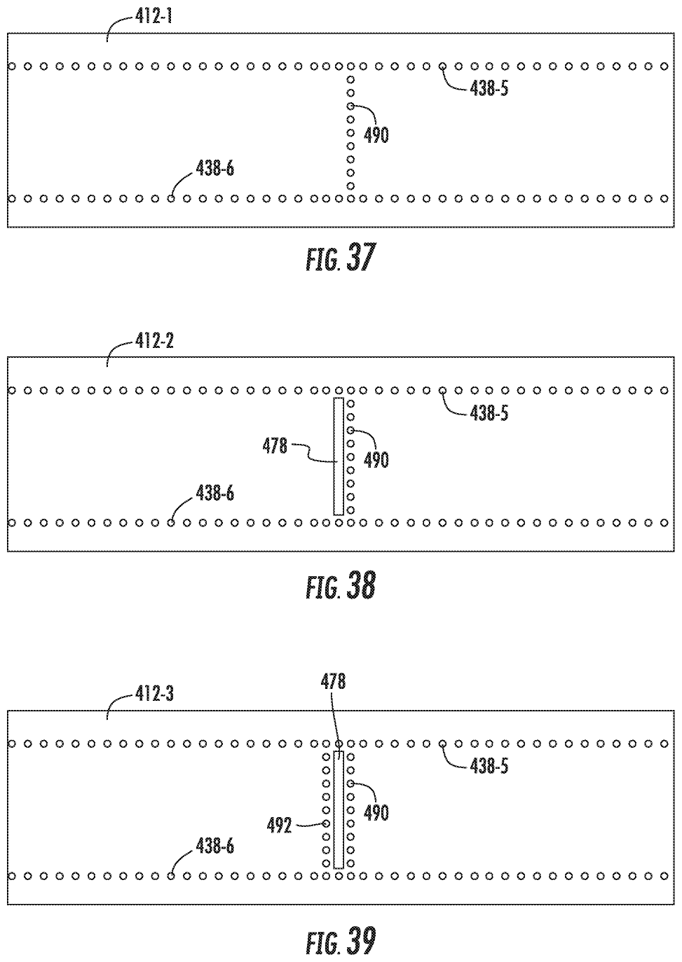

FIGS. 36-39 illustrate a printed circuit board structure 500 that includes such a vertical transition. In particular, FIG. 36 is a schematic perspective view of the printed circuit board structure 500, FIG. 37 is a plan top view of the printed circuit board structure 500, and FIGS. 38 and 39 are horizontal cross-sectional views taken along two of the internal patterned metal layers of the printed circuit board structure of FIG. 36. The printed circuit board structure 500 may correspond to the middle portion of the printed circuit board structure 400 of FIGS. 27-30. The vertical transition included in printed circuit board structure 500 may be identical to the vertical transition 460 included in the printed circuit board structures 400 and 400′, and hence further description of the printed circuit board structure 500 will be omitted.

FIG. 40 is a cross-sectional view of a modified version of the printed circuit board structure 500′ in which the substrate integrated waveguide transmission line segments run in opposite directions. In other words, FIG. 40 illustrates the substrate integrated waveguide counterpart to the vertical transition of FIGS. 23-26 for two co-planar waveguide transmission lines. As shown in FIG. 40, all but two of the RF leakage paths are blocked by the blind ground vias 590, 592.

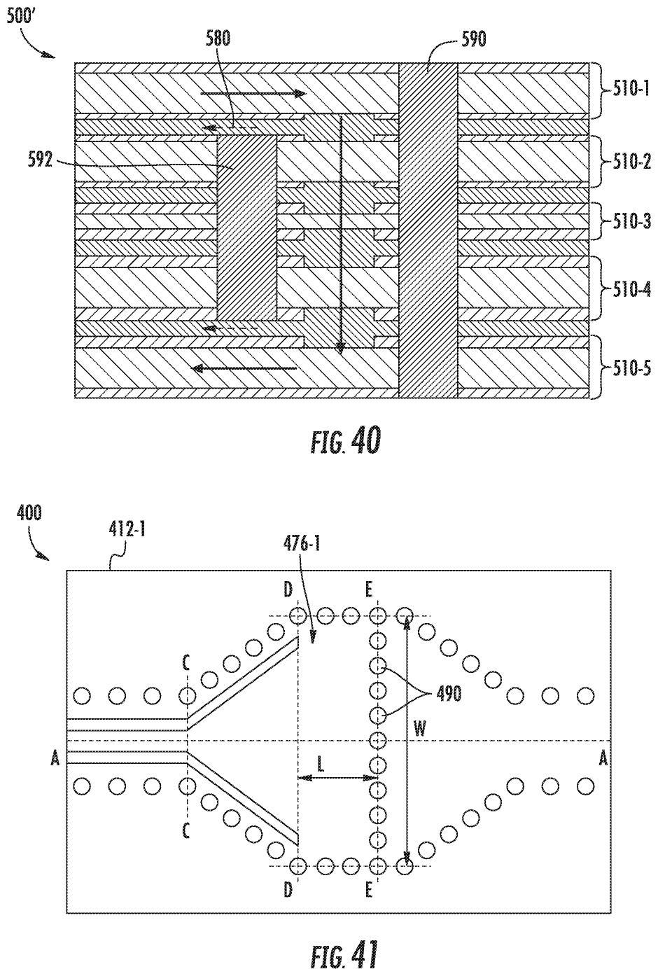

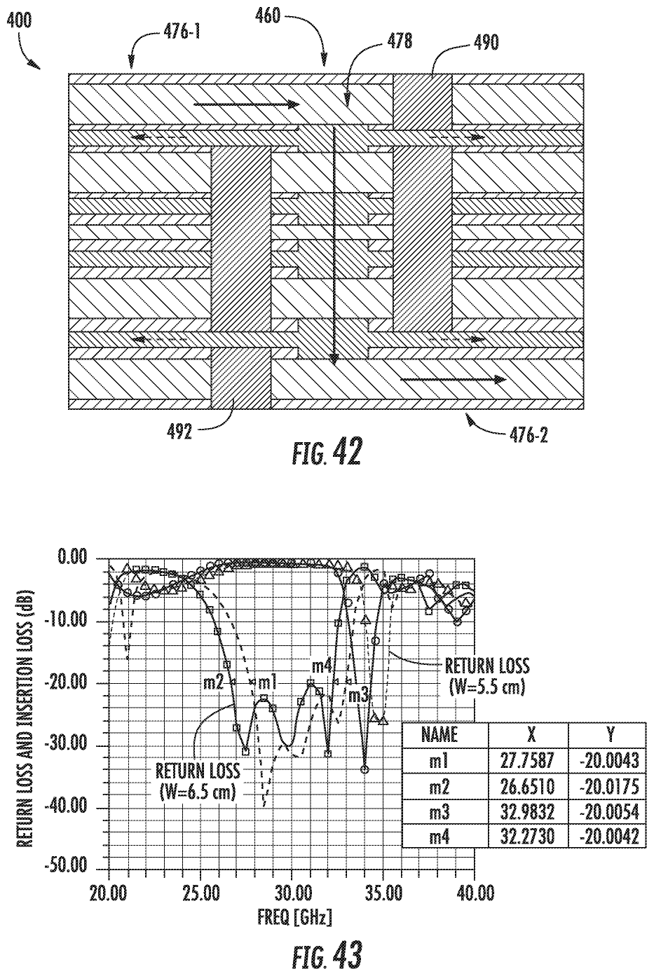

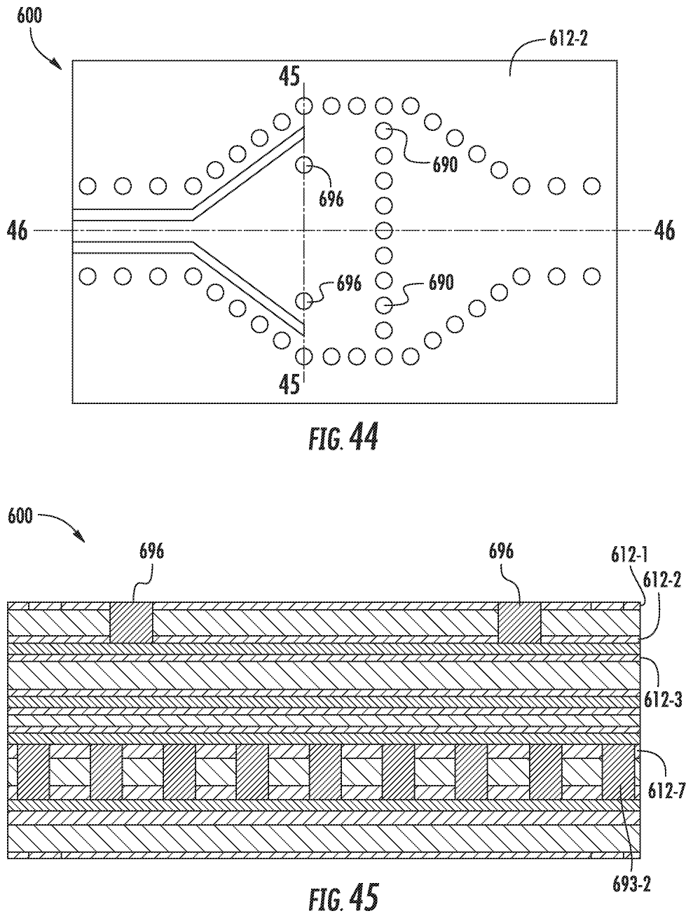

Pursuant to further embodiments of the present invention, RF transmission lines having vertical transitions are provided that have filtering features. In particular, FIGS. 41 and 42 are a top plan view and a cross-sectional view, respectively, of the printed circuit board 400 of FIGS. 27-30 with additional annotations added. Referring to FIGS. 41-42, it can be seen that the right side of the first substrate integrated waveguide transmission line segment 476-1 is blocked by the blind ground vias 490. As a result, the first substrate integrated waveguide transmission line segment 476-1 functions as a first cavity resonator. As shown in FIG. 42, the vertical waveguide section that is formed by the dielectric slot 478 functions as a second cavity resonator. Finally, the second substrate integrated waveguide transmission line segment 476-2 functions as a third cavity resonator. Additionally, the two 90 degree bends in the transmission line act as impedance transformers. Thus, it can be seen that the RF transmission lines 402, 402′, 502, 502′ of printed circuit board structures 400, 400′, 500, 500′ each may also act as a three-resonator filter. The passband of the filter may be defined by, among other things, the size of the three cavities and the thickness of the printed circuit board structure. For example, referring to FIG. 41, changing the width W of the substrate integrated waveguide transmission line segments 476 from 5.5 mm to 6.5 mm acts to shift the −20 dB return loss bandwidth from 27.8-33.0 GHz to 26.7-32.3 GHz, as is shown graphically in FIG. 43. Likewise, the length L of the substrate integrated waveguide transmission line segments 476 can be changed to modify the “passband” of the RF transmission line (i.e., the frequency band where the RF transmission line exhibits acceptable insertion loss and return loss performance).

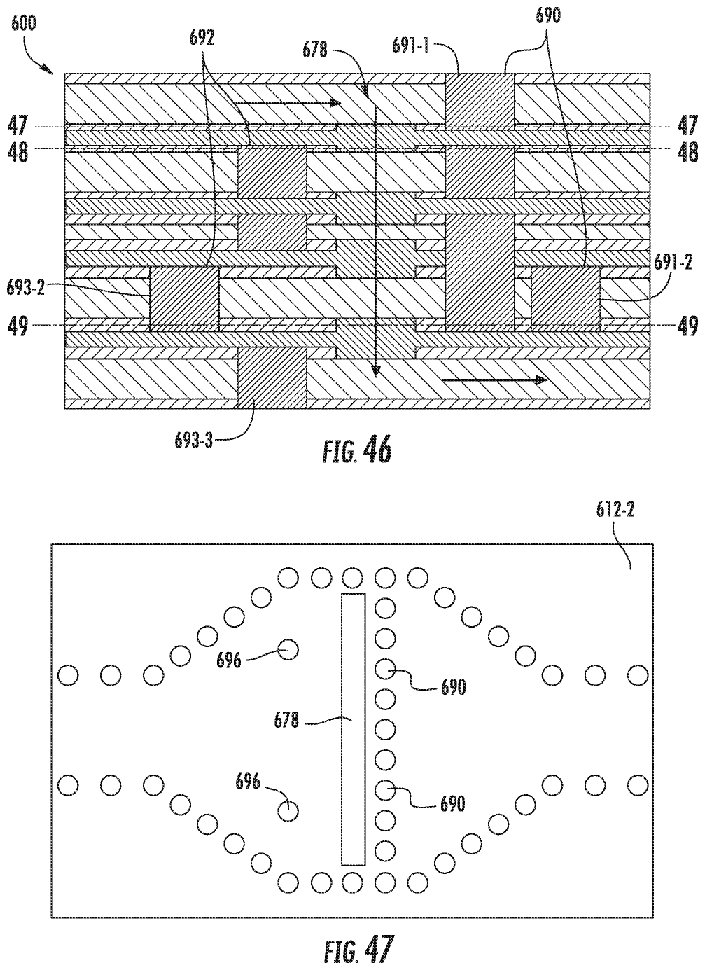

Pursuant to further embodiments of the present invention, pairs of shorter, offset blind ground vias 696 may be used in order to tune the filtering capability of the RF transmission lines according to embodiments of the present invention. FIGS. 44-49 illustrate a printed circuit board structure 600 according to further embodiments of the present invention that uses such offset blind ground vias 690, 692. In particular, FIG. 44 is a top plan view of the printed circuit board structure 600. FIGS. 45 and 46 are vertical cross-sections taken along lines 45-45 and 46-46, respectively, of FIG. 44. FIGS. 47-49 are horizontal cross-sections taken along lines 47-47, 48-48 and 49-49, respectively, of FIG. 46, which correspond to horizontal cross-sections through the second, third and seventh patterned metal layers 612-2, 612-3 and 612-7 of printed circuit board structure 600.

As shown best in FIG. 46, the blind ground vias 690, 692 are similar to the blind ground vias 490, 492 of printed circuit board structure 400. However, blind ground vias 690 are “offset vias” that include two offset segments 691 that do not vertically overlap. Similarly, blind ground vias 692 are also offset vias that include two offset segments 693 that do not vertically overlap. For example, blind ground via 690 includes a first segment 691-1 that does not vertically overlap a second segment 691-2. Similarly, blind ground via 692 includes a first segment 693-1 and a third segment 693-3 that vertically overlap with respect to each other but that do not vertically overlap with a second segment 693-2. The blind ground vias 690, 692 may be provided on either side of the dielectric slot 678 of the vertical transition and hence may still block the RF leakage paths. However, by including the lateral offset, the size of the vertical cavity resonator may be adjusted in order to tune the filter response of the RF transmission line 602. In effect, the vertical cavity resonator may include a horizontally-extending substrate integrated waveguide cavity that has an adjustable size that can be used to tune the filter response.

In addition, as shown in FIG. 45, two additional blind ground vias 696 are provided that penetrate the first and second patterned metal layers 612-1 and 612-2. The vias 696 are provided at the interface of the substrate integrated waveguide cavity and the co-planar waveguide to substrate integrated waveguide transition that connects thereto (i.e., along line 45-45 in FIG. 44). The vias 696 may be used to adjust the external Q factor of the substrate integrated waveguide cavity resonator.

In various of the above-described embodiments of the present invention a dielectric slot (e.g., slot 478) is formed in the printed circuit board structure that comprises a vertically extending column of dielectric material that extends through the interior of the printed circuit board structure. In the example embodiments disclosed herein, the dielectric slot has a rectangular horizontal cross-section. It will be appreciated that the rectangular slots that are etched in the patterned metal layers to form the vertically-extending column of dielectric material need not be identical, but instead can differ from one another in one or more dimensions. These differences in the openings in the patterned metal layer that define the dielectric slot may be used to further tune the filtering effects of the vertical transitions according to embodiments of the present invention.

While the above-description focuses on the filtering aspects of the RF transmission lines according to embodiments of the present invention that include substrate integrated waveguide transmission line segments, it will be appreciated that similar filtering may occur in embodiments of the present invention that include co-planar waveguide transmission line segments. Thus, it will be appreciated that the filter response of any of the RF transmission lines described herein may be tuned using any of the techniques (e.g., offset blind ground vias, bind ground vias for adjusting the external Q-factor, changing the width and/or the length of the horizontal resonant cavities, etc.) described herein.

While the above embodiments illustrate vertical transitions that are used to connect horizontally-extending transmission lines that are implemented in the top and bottom layers of a multi-layer printed circuit board, it will be appreciated that each of the vertical transitions described herein could also be modified to connect horizontally-extending transmission lines that are on two intermediate layers of a multi-layer printed circuit board or to connect horizontally-extending transmission lines that are implemented in the top layer or bottom layer of a multi-layer printed circuit board to an intermediate layer of the multi-layer printed circuit board.

While the present invention is primarily described above with reference to printed circuit boards or other multi-layer substrates for system-in-package RF communications systems, it will be appreciated that the RF transmission lines and vertical transitions described herein may be used in non-system-in-package systems and/or in systems other than RF communications systems. For example, RF test equipment could employ any of the RF transmission lines and vertical transitions described herein

Pursuant to further embodiments of the present invention, methods of forming RF transmission lines having vertical transitions in a multi-layer printed circuit board are provided. Pursuant to these methods, a first printed circuit board (e.g., printed circuit board 210-1) is formed that includes a first transmission line segment and a first conductive ground via. A second printed circuit board (e.g., printed circuit board 210-5) is formed that includes a second transmission line segment and a second conductive ground via. Additionally, at least one additional printed circuit board (e.g., printed circuit boards 210-2 through 210-4) is formed that has a third conductive ground via and a fourth conductive via. A first additional dielectric layer (e.g., additional dielectric layer 216-1) is used to adhere the first printed circuit board to the at least one additional printed circuit board. A second additional dielectric layer (e.g., additional dielectric layer 216-4) is used to adhere the second printed circuit board to the at least one additional printed circuit board. Once the printed circuit boards are adhere together, the first conductive ground via is vertically aligned with the third conductive ground via to form a first blind ground via and the second conductive ground via is vertically aligned with the fourth conductive ground via to form a second blind ground via.

In some embodiments, the second blind ground via may vertically overlap the first transmission line segment and the first blind ground via may vertically overlap the second transmission line segment. In some embodiments, the at least one additional printed circuit board may comprise a plurality of additional printed circuit boards. In some cases, these additional printed circuit boards may first be adhered together and then the third and fourth conductive ground vias may be formed by drilling a pair of holes through the stack of additional printed circuit boards and then plating the pair of holes to form the third and fourth conductive ground vias.

It will be appreciated that many modifications may be made to the above described embodiments without departing from the scope of the present invention.

Herein, references are made to one element such as a blind ground via “vertically overlapping” another element such as a transmission line segment. Such references to two “vertically overlapping” elements means that a vertical axis (i.e., an axis that extends perpendicularly to the multi-layer printed circuit board structures according to embodiments of the present invention) extends through both elements.

Herein references are made to printed circuit boards and printed circuit board structures. It will be appreciated that the term printed circuit board is used broadly to refer to a dielectric layer that has a metal layer (which may or may not be patterned) adhered to at least one major surface thereof. A printed circuit board structure is a structure that includes at least one printed circuit board.

The present invention has been described above with reference to the accompanying drawings. The invention is not limited to the illustrated embodiments; rather, these embodiments are intended to fully and completely disclose the invention to those skilled in this art. In the drawings, like numbers refer to like elements throughout. Thicknesses and dimensions of some elements may not be to scale.

Spatially relative terms, such as “under”, “below”, “lower”, “over”, “upper”, “top”, “bottom” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Well-known functions or constructions may not be described in detail for brevity and/or clarity. As used herein the expression “and/or” includes any and all combinations of one or more of the associated listed items.

It will be appreciated that aspects of all embodiments disclosed herein may be combined in different ways to provide numerous additional embodiments. Thus, it will be appreciated that elements discussed above with respect to one specific embodiment may be incorporated into any of the other embodiments, either alone or in combination.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

1. A radio frequency (“RF”) transmission line in a multi-layer printed circuit board structure, comprising:
a first row of ground vias that extend vertically through the multi-layer printed circuit board structure;
a second row of ground vias that extend vertically through the multi-layer printed circuit board structure;
a first transmission line segment extending horizontally along a first portion of the multi-layer printed circuit board structure;
a second transmission line segment extending horizontally along a second portion of the multi-layer printed circuit board structure, the second transmission line segment vertically spaced apart from the first transmission line segment;
a vertical dielectric structure that extends between the first and second transmission line segments; and
a blind ground via that extends vertically through the printed circuit board structure positioned adjacent the vertical dielectric structure.

2. The RF transmission line of claim 1, wherein at least one of the first transmission line segment and the second transmission line segment extends between the first and second rows of ground vias.

3. The RF transmission line of claim 2, wherein the blind ground via extends to one of a top surface or a bottom surface of the printed circuit board structure.

4. The RF transmission line of claim 2, wherein the blind ground via is a buried blind ground via having a top end and a bottom end that are both within an interior of the printed circuit board structure.

5. (canceled)

6. The RF transmission line of claim 1, wherein a plurality of blind ground vias are provided between the first and second rows of ground vias.

7-8. (canceled)

9. The RF transmission line of claim 6, wherein the blind ground via comprises a first blind ground via that vertically overlaps and is isolated from the first transmission line segment and a second blind ground via that vertically overlaps and is isolated from the second transmission line segment.

10. The RF transmission line of claim 1, wherein the first transmission line segment is implemented in an uppermost printed circuit board of the printed circuit board structure, and the second transmission line segment is implemented in a lowermost printed circuit board of the printed circuit board structure, and wherein the blind ground via comprises a first set of blind ground vias that extend completely through the uppermost printed circuit board on a first side of the vertical dielectric structure and a second set of blind ground vias that extend completely through the lowermost printed circuit board on a second side of the vertical dielectric structure that is opposite the first side.

11. The RF transmission line of claim 1, wherein the blind ground via is between the first row of ground vias and the second row of ground vias adjacent a distal end of the first transmission line segment.

12. The RF transmission line of claim 1, wherein the multi-layer printed circuit board structure comprises a plurality of printed circuit boards, each printed circuit board including a core dielectric layer and at least one patterned metal layer, and a plurality of additional dielectric layers that bind the printed circuit boards together.

13-15. (canceled)

16. The RF transmission line of claim 1, further comprising a conductive signal via that extends between the first and second transmission line segments.

17. The RF transmission line of claim 16, further comprising a plurality of vertically spaced-apart annular metal pads that surround the conductive signal via.

18. The RF transmission line of claim 17, further comprising a plurality of annular void rings that define an annular dielectric column that surround the plurality of vertically spaced-apart annular metal pads, the annular dielectric column comprising the vertical dielectric structure.

19. (canceled)

20. A radio frequency (“RF”) transmission line in a multi-layer printed circuit board structure, comprising:
a first transmission line segment extending horizontally along a first portion of the multi-layer printed circuit board structure;
a second transmission line segment extending horizontally along a second portion of the multi-layer printed circuit board structure, the second transmission line segment vertically spaced apart from the first transmission line segment;
a vertical dielectric structure that extends between the first and second transmission line segments;
a first ground via that vertically overlaps the first transmission line segment; and
a second ground via that vertically overlaps the second transmission line segment.

21. The RF transmission line of claim 20, wherein the first and second ground vias each comprise blind ground vias that that extend vertically through the printed circuit board structure and that each have an end that terminates within an interior of the printed circuit board structure.

22. The RF transmission line of claim 21, further comprising:
a first row of ground vias that extend vertically through the printed circuit board structure; and
a second row of ground vias that extend vertically through the printed circuit board structure,
wherein at least one of the first transmission line segment and the second transmission line segment extends between the first and second rows of ground vias.

23. The RF transmission line of claim 22, wherein the first and second blind ground vias are each a buried blind ground via having a top end and a bottom end that are both within an interior of the printed circuit board structure.

24-26. (canceled)

27. The RF transmission line of claim 21, wherein the first and second blind ground vias are on opposed sides of the vertical dielectric path.

28-34. (canceled)

35. A radio frequency (“RF”) transmission line in a multi-layer printed circuit board structure, comprising:
a first row of ground vias that extend vertically through the multi-layer printed circuit board structure;
a second row of ground vias that extend vertically through the multi-layer printed circuit board structure;
a first transmission line segment extending horizontally along a first portion of the multi-layer printed circuit board structure;
a second transmission line segment extending horizontally along a second portion of the multi-layer printed circuit board structure, the second transmission line segment vertically spaced apart from the first transmission line segment; and
a first blind ground via that is adjacent the distal end of the first transmission line segment between the first and second rows of ground vias.

36-40. (canceled)

41. The RF transmission line of claim 35, wherein the first blind ground via vertically overlaps and is isolated from the first transmission line segment, the RF transmission line further comprising a second blind ground via that vertically overlaps and is isolated from the second transmission line segment.

42-43. (canceled)

44. The RF transmission line of claim 35, wherein the first blind ground via is an offset blind ground via that includes first and second segments that do not vertically overlap.

45-49. (canceled)
